(19) United States
(12) Patent Application Publication
(10) Pub. No.: US 2012/0050206 A1
(43) Pub. Date: Mar. 1, 2012

(54) MULTI-TOUCH RESOLVE MUTUAL CAPACITANCE SENSOR

(76) Inventor: DAVID WELLAND, AUSTIN, TX (US)

(21) Appl. No.: 12/870,844

(22) Filed: Aug. 29, 2010

(51) Int. Cl. G06F 3/045; G01R 27/26

(52) U.S. Cl. 345/174; 324/679

(57) ABSTRACT

A method for interfacing with a capacitive touch screen is disclosed. The method includes charging an internal capacitor in the touch screen, which internal capacitor is disposed proximate a fixed location on the touch screen and is capable of changing in response to a touch at the specific location. After charging, the charge on the internal capacitor is transferred from the touch screen and the value of the charge on the internal capacitor then determined.

### CROSS-REFERENCE TO RELATED APPLICATIONS

This application is related to co-pending U.S. patent application Ser. No. 12/775,447, filed May 6, 2010 entitled METHOD AND APPARATUS FOR SCANNING A TOUCHSCREEN WITH MULTI-TOUCH DETECTING USING MASTER/SLAVE DEVICES (Atty. Dkt. No. 29,953) and U.S. patent application Ser. No. ______, filed ______, entitled ______ (Atty. Dkt. No. CYGL-30,121) which is incorporated herein in its entirety.

### TECHNICAL FIELD

The present invention pertains in general to touch screens and, more particularly, to a touch screen with Multi-Touch Resolve (MTR) capabilities.

### BACKGROUND

Capacitive touch screens have been utilized recently to allow a user to provide a user interface with touch capability on such things as Personal Digital Assistants (PDAs), tablet PCs, etc. These touch screens function by detecting a change in capacitance at a particular location as opposed to a physical interaction with the screen, such as is the case with a stylus based system. With capacitance based touch screens, a finger is typically placed onto the screen which will change the capacitance of a region thereon. This region could be a touch pad or it could be a touch screen array which is comprised of an array of column lines and intersecting row lines. By detecting the capacitance of a row line, for example, a difference in capacitance on a particular row line can be detected, as is also the case with respect to the column line. If just the capacitance of a row line or the capacitance of a column line is utilized as the discriminating factor, an ambiguity may exist when merely detecting the static capacitance on these lines in the presence of multiple touches on the screen. The reason for this is that static capacitance measuring devices merely determine that a particular row line was touched and a particular column line was touched. For two touches, all that is known is that two row lines have been touched and two column lines have been touched, but the exact intersection can not be determined. To rectify this, Multi-Touch Resolve (MTR) techniques have been employed to detect a change in capacitance of the row-to-column capacitance (C_{RCF}). These techniques typically utilize some type of signal that is injected into a row line and coupled across C_{RCF} to a column line. A detector on the column line can detect this signal level. By comparing the signal level in the presence of a touch to the signal level in the absence of a touch, a determination can be made as to the presence of the touch due to a change in the signal level.

### SUMMARY

The present invention disclosed and claimed herein comprises, in one aspect thereof, a method for interfacing with a capacitive touch screen. The method includes charging an internal capacitor in the touch screen, which internal capacitor is disposed proximate a fixed location on the touch screen and is capable of changing in response to a touch at the specific location. After charging, the charge on the internal capacitor is transferred from the touch screen and the value of the charge on the internal capacitor then determined.

### BRIEF DESCRIPTION OF THE DRAWINGS

For a more complete understanding, reference is now made to the following description taken in conjunction with the accompanying Drawings in which:

FIG. 1 illustrates a diagrammatic view of a scan control IC interfaced with a display;

FIG. 2 illustrates a more detailed diagram of the scan control IC illustrating the two scan interfaces associated therewith;

FIGS. 3a and 3b illustrate a more detailed diagram of the overall scan control IC;

FIG. 4 illustrates a schematic of the I/O pad;

FIG. 5 illustrates a diagrammatic view of a touch panel illustrating the row-to-column capacitance at the interface with the ADCs;

FIG. 6 illustrates a more detailed diagram of the row and column intersections for a touch screen and the capacitance associated therewith;

FIG. 7 illustrates a circuit diagram for the voltage sampling step of the conversion operation;

FIG. 8 illustrates a basic diagram for the ADCs associated with the MTR function;

FIG. 9 illustrates a timing diagram for the MTR operation and the three phases thereof;

FIG. 10 illustrates the auto zero configuration for the ADC and the MTR;

FIG. 11 illustrates the transfer mode for the ADC and the MTR;

FIG. 11a illustrates an alternate view of the embodiment of FIG. 10;

FIG. 12 illustrates the conversion phase for the ADC of the MTR block;

FIG. 13 illustrates a detail of the SAR conversion operation;

FIG. 14 illustrates a diagrammatic view of the top level power domain architecture;

FIG. 15 illustrates a diagrammatic view of the decision process for determining touch and no touch;

FIG. 16 illustrates a simplified diagram of the hardware controller interfacing with the memory;

FIG. 17 illustrates a more detailed diagram of the hardware controller;

FIG. 18 illustrates a block diagram of the interface between the MTR module 114 and the DMA 354;

FIG. 19 illustrates the clock generator;

FIG. 20 illustrates the control flow between the two clock mains of the MTR and the SYSCLK;

FIG. 21 illustrates the synchronization circuitry between two clocks;

### DETAILED DESCRIPTION

Referring now to the drawings, wherein like reference numbers are used herein to designate like elements throughout, the various views and embodiments of a touch screen scanning architecture are illustrated and described, and other possible embodiments are described. The figures are not necessarily drawn to scale, and in some instances the drawings have been exaggerated and/or simplified in places for illustrative purposes. One of ordinary skill in the art will appreciate the many possible applications and variations based on the following examples of possible embodiments.

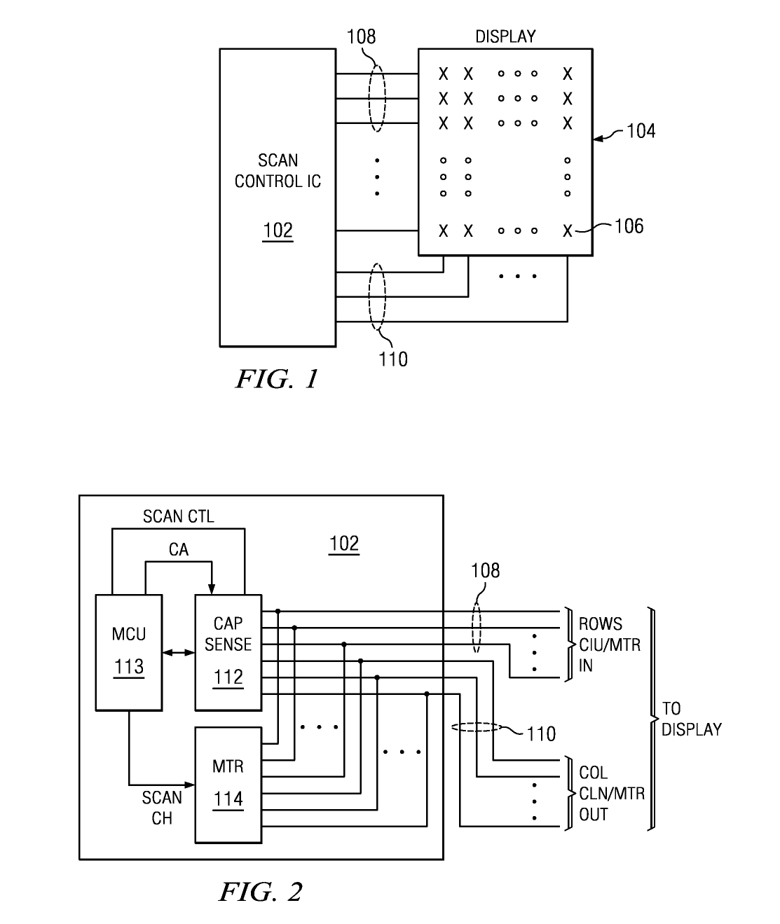

Referring now to FIG. 1, there is illustrated a diagrammatic view of a scan control IC 102 that is interfaced with a touch screen 104 that can be used by itself or in conjunction with a display as an overlay. The touch screen 104 is a touch screen having a plurality of distributed capacitors 106 disposed at intersections of columns and rows. There are a plurality of rows 108 and a plurality of columns 110 interfaced with the scan control IC. Thus, a row line will be disposed across each row which intersects with a column line on the touch screen surface and these are interfaced with the scan control IC 102. It should be understood that a capacitive touch pad or detection area refers to an area on the touch screen, but will be used to refer to an intersection between a row line and a column line. The term “touch pad” and “intersection” shall be used interchangeably throughout.

Referring now to FIG. 2, there is illustrated a more detailed diagrammatic view of the scan control IC 102. In determining a change in capacitance for a particular row or column line, there can be multiple techniques utilized. The first technique is to merely sense the value of the self capacitance for all or a select one or ones of the row or column lines and then utilize some type of algorithm to determine if the capacitance value has changed and then where that change occurred, i.e., at what intersection of row and column lines. The scan control IC 102 provides this functionality with a capacitive sense block 112. This block 112 functions to determine if a change has occurred in the self capacitance value of the particular row or column line to ground. Another technique is that referred to as a “multi-touch resolve” (MTR) functionality provided by an MTR module 114. This is for sensing changes in the mutual capacitance at the intersection of a row and column line, i.e., the row-to-column capacitance C_{RCF}.

The capacitive sense block capacitive-to digital converter 112 is basically controlled to scan row and column lines and determine the self capacitance thereof to ground. If a change in the self capacitance occurs, this indicates that some external perturbance has occurred, such as a touch. By evaluating the self capacitance values of each of the rows and columns and comparing them with previously determined values, a determination can be made as to where on the touch screen a touch has been made. However, if multiple touches on the touch screen have occurred, this can create an ambiguity. The MTR module 114, as will be described in more detail herein below, operates to selectively generate a pulse or signal on each of the row lines and then monitor all of the column lines to determine the coupling from the row line to each of the column lines. This provides a higher degree of accuracy in determining exactly which intersection of a particular row and column was touched.

Each of the column lines is monitored to determine the value of signal coupled across the row-to-column intersection with the row line being driven by the pulse or signal. Thus, if a pulse or any type of signal is input on a particular row line, for example, the change in the signal coupled across the intersection between that column line and a row line having a finger disposed across the particular intersection will be noticeable since this particular intersection will exhibit the highest change in mutual capacitance. In general, the mutual capacitance across the intersection between row and column lines will actually decrease when a finger is disposed in close proximity thereto. It should be understood that the pulse could be generated on column lines and the row lines sensed, as opposed to the illustrated embodiment wherein the pulse is generated on the column lines and then the row lines sensed, and row and column lines shall be utilized in the description herein in an interchangeable manner. It is noted that for each generation of a pulse, all of the column lines are monitored at substantially the same time depending upon inherent delays in circuitry and the such. This could be facilitated with dedicated analog-to-digital converters for each row/column line or a multiplexed bank of such. As will be described herein below, a pulse input is used in conjunction with a charge transfer technique.

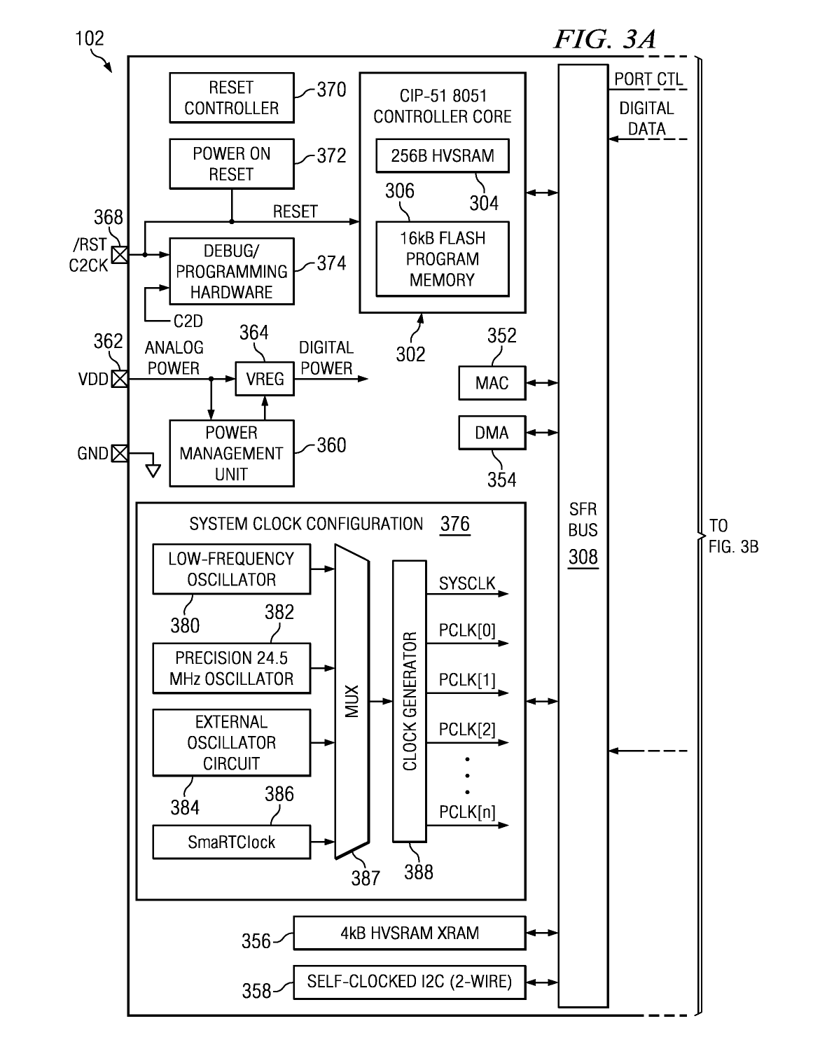

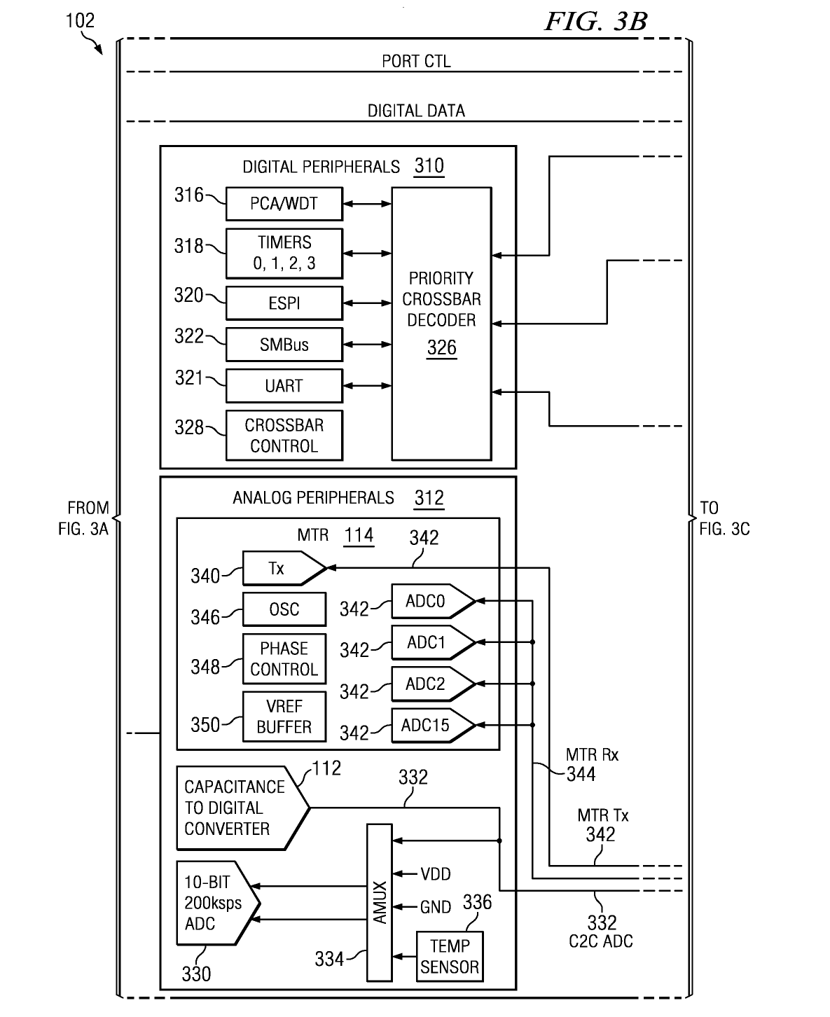

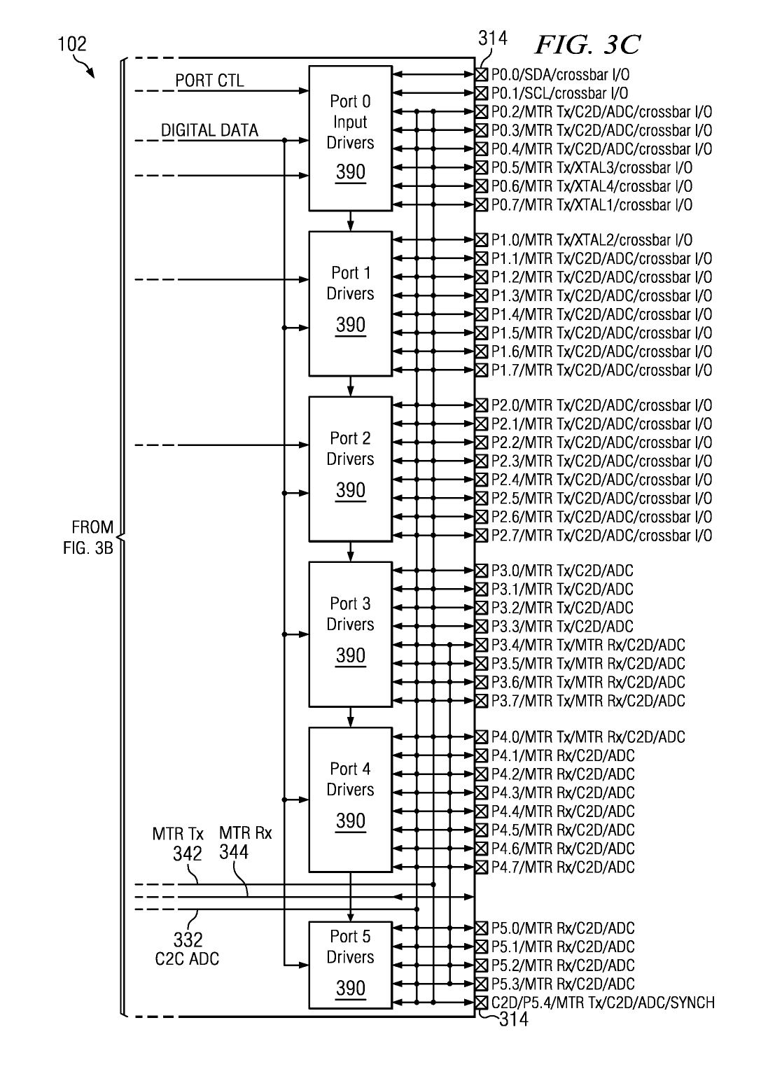

Referring now to FIG. 3a, there is illustrated a more detailed block diagram of the scan control IC 102. At the heart of the scan control IC 102 is an 8051 central processing unit (CPU) 302. The scan control IC 102 is basically a microcontroller unit (MCU) which is described in detail in U.S. Pat. No. 7,171,542, issued Jan. 30, 2007 to the present assignee and entitled RECONFIGURABLE INTERFACE FOR COUPLING FUNCTIONAL INPUT/OUTPUT BLOCKS TO LIMITED NUMBER OF I/O PINS, which is incorporated herein by reference in its entirety. The 8051 processing core 302 includes XRAM 304 and flash memory 306, the flash memory utilized to store program instructions, which memory constitutes non-volatile memory. The 8051 processing core 302 interfaces with various peripheral circuitry on the IC 102 such as contained in a digital peripherals block 310. The interface is provided by a Special Function Register (SFR) bus 308 which allows the processing core 302 to interface with the various peripherals via Special Function Registers (SFRs), these registers being addressable registers within the address spaces of the processing core 302 that allow the processing core 302 to store data therein for use by the digital peripherals and for the peripherals to store processed data or receive data therein for use by the processing core 302. This effectively provides a “gateway” for data back and forth between the various peripherals. The terms CPU, processing core and MCU will be used interchangeably throughout, as the MCU is a combination of the processing core (CPU) 302, memory and peripherals that allow the CPU 302 to carry out the various functions of the overall IC.

The digital peripheral block 310 is one set of peripherals operating in the digital domain and an analog peripheral block 312 provides analog peripherals. These peripherals provide an interface between an interface for the IC 102 to the external world through various external pins. These external or output port pins are illustrated in FIG. 3b and designated by reference numeral 314.

The digital peripheral block 310 includes a watch dog timer block 316, various timers 318, a serial peripheral interface block 320, an SMBus block 322 and a UART block 324. All of these blocks 316-324 are interfaced to a priority crossbar decoder 326. The priority crossbar decoder 326 is operable to be configured by a crossbar control block 328 in order to interface the various peripherals 316-324 with select ones of the output port pins 314. This is described in detail in U.S. Pat. No. 7,171,542, which was incorporated by reference herein above. The priority crossbar decoder 326 is utilized for the digital interface and will allow such things as the UART 324 to be interfaced with select pins on the output port pins 314 and these can be user configured for any pins that are desired to be associated therewith. The SMBus 322 utilizes a 2-wire serial bus interface utilizing a clock and a data line and this clock and data line utilize two pins and these can be configured for any two of the select pins. As described in U.S. Pat. No. 7,171,542, these pins, once assigned, can take priority over other pins.

The analog peripheral block 312 includes the cap sense block 112 and the MTR module 114 in addition to including an analog-to-digital converter (ADC) 330. This ADC 330 is a 10-bit ADC which is interfaced with a CDC/ADC bus or analog line 332, this bus or line 332 also interfaced with the input to the capacitive sense block 112. An analog multiplexer 334 is provided for interface between the ADC 330 and the bus 332 such that it can select the bus 332 or other analog peripherals. The analog inputs interfaceable to the bus 332 are typically scanned inputs such that the ADC 330 can selectively sample the analog values thereon by enabling the I/O pad associated with a desired pin designated as an analog input and convert these to digital values. In addition, the multiplexer 334 allows for sensing of the supply voltage, the ground voltage and a voltage associated with an on-chip temperature sensor 336. This temperature sensor 336 is basically associated with a voltage generated by a band gap generator (not shown) which generates various voltages for the operation of the analog circuitry on the IC 102. This is a conventional circuit that provides temperature stabilized voltage sources. By providing for selection of the temperature input, a temperature measurement can be provided which is utilized, as will be described herein below, for calibration of the MTR module 114. It is also used for other functions which are not described herein.

As will be described in more detail herein below, the MTR module 114 is comprised of a transmitter 340 which is operable to transmit a pulse on a negative going edge. This is provided as a driving signal on a single line bus 341. This can be selectively output to one of multiple pins associated with that functionality by enabling a desired I/O pad as an analog output. Additionally, there are provided dedicated ADCs 342 which each interface with one of 16 different input pins on a bus 344. This comprises the MTR Rx inputs, whereas the bus 341 comprises the MTR Tx output. There are 16 ADCs 342 to allow for simultaneous interface to 16 different MTR Rx inputs such that bus 344 has a width of 16. As will be described herein below, each of these ADCs 342 receives one of the 16 inputs in parallel and processes those values in parallel. These are dedicated to the MTR functionality. It should be understood that less than 16 ADCs 342 could be utilized by multiplexing the operation thereof.

In addition to the transmitter 340 and the receive ADCs 342, there is also provided a peripheral oscillator 346 such that the MTR module 114 is a “self-clocked” peripheral. This self clocking allows the MTR module 114, and other such self clocked analog peripherals, to operate when the digital circuitry including clocking circuitry is asleep. The MTR block could also operate on the system clock. This oscillator 346 utilizes an RC oscillator circuit that can run independently or be synched up with an external clock. However, when this oscillator 346 is running, it is asynchronous with respect to the system clock (described herein below) that is utilized to provide timing for the entire chip when running During various low power modes, the system clock circuitry is halted or powered down and, as such, for the MTR module 114 to operate and scan a particular touch screen, an internal self contained clock is utilized. This will be described in more detail herein below. There is also provided a phase control 348 for control of different MTR operational phases and a V_{REF} buffer 350. This V_{REF} buffer is utilized to sense a reference voltage, which in the case of the MTR module 114 is the supply voltage, and latch it onto a node or, in other words, “freeze” this value during the operation of the ADC 342 conversion operation in order to remove noise. This will be described in more detail herein below.

The 8051 processing core 302, when performing certain operations, utilizes a Multiply Accumulate Block (MAC) 352 to allow certain multiply and accumulate operations to be carried out in the hardware. Additionally, there is a Direct Memory Access (DMA) block 354 that allows the peripheral units and other peripheral blocks to interface directly with an HVSRAM or XRAM memory 356 through the SFR Bus 308 to allow reading and writing of data therewith out requiring the 8051 processing core 302. Thus, any of the blocks associated with peripheral functions can utilize the DMA 354 to write data to the memory 356 and extract data therefrom. There is also provided a self clocked 12C block 358, which is a self-clocked serial data communication peripheral block that has associated therewith two dedicated pins to allow external chips to interface with the digital portion IC 102. Since this is self-clocked, it can operate when the IC 102 is in a sleep or idle mode. This I2C peripheral block 358 can also interface directly with the memory 356 through the DMA 354 such that an external device can directly read and write to the memory 356 through the I2C peripheral block 358.

There is provided a power management unit (PMU) 360 that is operable to interface with the V_{DD} battery voltage or power supply voltage on a power supply pin 362 in order to provide power to the chip. This is typically provided by a battery. The chip power is divided up into analog power, i.e., unregulated power, and digital power which is provided through a regulator 364. This is an LDO regulator that provides the digital voltage. Typically, the battery voltage can run between 1.8-3.6 volts and this is regulated down to a voltage comparable for operating the digital portion of the chip. The power management unit 360 controls the operation of the regulator 364. This regulator 364 is a regulator that can be powered down during sleep mode. This is described in U.S. patent application Ser. No. 11/865,661, filed Oct. 1, 2007, entitled POWER SUPPLY SYSTEM FOR LOW POWER MCU, which is incorporated herein by reference in its entirety.

In addition to the power management, there is also provided a reset and serial clock input on external pin 368 which is operable to provide for a Reset input and also to allow a serial control clock to be input for data input, debugging, etc. The Reset is controlled by a reset controller 370 and a power on reset block 372. Various debugging programming hardware in block 374 is also provided which is controlled by the C2 Data (CDC) which is received on another input and utilizes the C2 clock signal on pin 368 therefor. The CDC is derived from another input or pin.

All of the system clocks are provided by a system clock block 376. It should be understood that these system clocks are what are utilized for the digital operation and are to be distinguished from the internal clocks and the various self-clocked blocks such as the MTR module 114 and the I2C block 358. The system clocks are comprised of an on-chip, low frequency oscillator 380, a precision oscillator 382, an external oscillator circuit 384 and a smart clock block 386, this smart clock block comprising an RTC clock. This is a 32 kHz clock. Although not illustrated, there is provided an RTC function on the chip which is described in U.S. Pat. No. 7,343,504, issued Mar. 11, 2008 to the present assignee, entitled MICROCONTROLLER UNIT (MCU) WITH RTC, which is incorporated herein by reference in its entirety.

With specific reference to FIG. 3b, there is illustrated a diagrammatic view of the pin out configuration for the output port pins 314. These are the peripheral pins which allow the IC 102 to interface with various external devices such as displays, sensors and control lines. Each of these output port pins 314 is associated with an I/O pad (not shown). This I/O pad allows the output port pin 314 to be configured as a digital input/output pad or as an analog input/output pad. It should be understood that some of the output port pins 314 and the associated I/O pads can be manufactured such that they primarily have either a digital function or an analog function. This is a design choice, but it should be understood that each of the output port pins 314 could be given the functionality to accommodate both analog and digital signals.

When dealing with a digital interface, port drivers or pin interface circuits 390 are provided to interface with the various output port pins 314 when driving a digital value thereto. There are provided six port drivers for port 0, port 1, . . . port 5. As can be seen from the labels, the output port pins 314 associated with port 0, port 1 and port 2 drivers 390 can be associated with the crossbar decoder 326 and, as such, those are the only output port pins 314 that can be interfaced with the digital peripherals in block 310 in this example. However, it can be seen that the bus 341, a single wire bus, for the MTR transmitter 340 can be selectively interfaced to thirty two (32) of the output port pins 314 and, as such, the bus 341 is interfaceable therewith. For the MTR receive function, there is provided a sixteen line MTR Rx bus 342, as there are sixteen MTR ADCs 342. There are provided thirty six output port pins 314 interfaceable with the ADC 330 and thirty nine of the output port pins 314 associated with the CDC capacitive sense function through lines 332, a single line bus. Basically, anything that is associated with the CDC capacitive sense functionality will also be associated with the ADC 330, since they share a common bus 332. Thus, each of these pins will have an analog input capability via the associated I/O pad for selecting such. Although not shown, one of the pins will have a dedicated functionality associated with a SYNC function which is only utilized when multiple ones of the IC 102 are configured in a multi-chip operation and this will be connectable to the MTR Tx bus 341 such that respective pins 314 will be associated therewith.

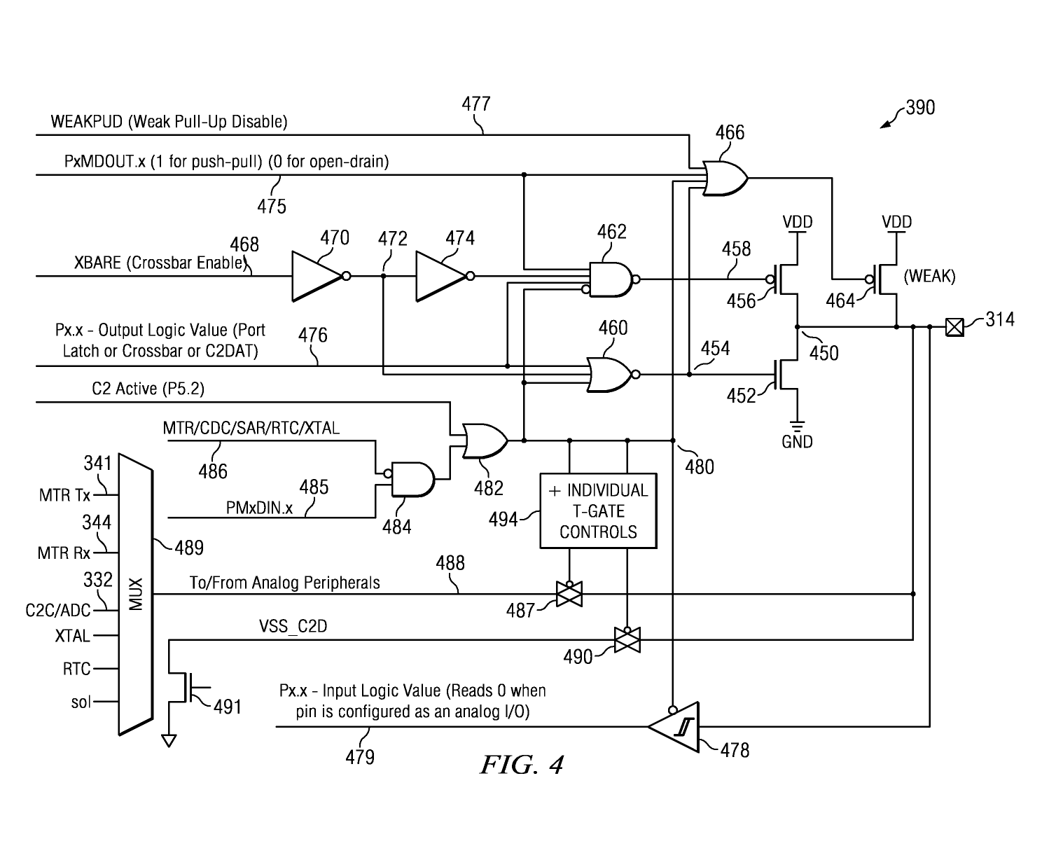

Reference is now made to FIG. 4 where there is shown in functional detail of one pin interface circuit 390, the I/O pad. The other pin interface circuits are constructed and operate in an identical manner, it being understood that some pin interface circuits primarily interface with digital data. While the various logic functions carried out by the pin interface circuit 390 are shown as implemented by traditional logic gates, in practice such functions are carried out by various types of transistor circuits which perform the logic functions. Those skilled in the art can readily devise many different types of transistor circuits to carry out the noted logic functions. Many of the signals coupled to the pin interface circuit 390 are generated by the CPU 302 and some by the analog peripherals 312. In the preferred embodiment, a triplet of the signals is coupled to each pin interface circuit by way of a priority cross-bar decoder. The cross-bar decoder circuit is described in detail in issued patents of the assignee identified as U.S. Pat. No. 6,839,795, issued Jan. 4, 2005 and U.S. Pat. No. 6,738,858, issued May 18, 2004, the subject matter of such patents being incorporated herein by reference.

The pin interface circuit 390 is operable to accommodate a digital I/O function to drive the port with a digital signal or to act as a digital input and receive a digital signal and also to function as an analog I/O port. The digital functionality is facilitated in a driver functionality wherein the output port pin 314 is driven from a node 450 that has the ability to operate as a push-pull node or an open-drain node. In the push-pull operation, an N-channel transistor 452 has the source/drain path thereof connected between node 450 and ground, node 450 connected to the output port pin 314. The gate of transistor 452 is connected to a node 454. A P-channel transistor 456 has the source/drain path thereof connected between node 450 and V_{DD}. The gate of transistor 456 is connected to a node 458. Node 454 is driven by the output of a NOR gate 460 and the gate of transistor 456 is driven by the output of a NAND gate 462. For the open-drain digital output function, there is also provided a weak pull up transistor 464, which is comprised of a P-channel transistor having a source/drain path thereof connecting node 450 and V_{DD} and the gate thereof being driven by an OR gate 466.

When the port is enabled as a digital output, a crossbar encoder enable signal X-BAR is provided as an input on an input node 468. This input 468 drives the input of inverter 470, the output thereof connected to a node 472, node 472 connected to the input of an inverter 474 that drives one input of the NAND gate 462. Node 472 is connected to one input of the NOR gate 460. A control signal received on a node 475 controls whether a particular port is a push-pull port or an open-drain port. This control signal on line 475 is input to one input of the OR gate 466. If it is a logic “1,” this indicates a push-pull operation such that the gate of transistor 464 is at a logic high, thus disabling transistor 464. The signal on node 475 is also input to one input of the NAND gate 462. The output logic value that drives the port when configured as a digital output is provided on a digital input port 476 to drive both one input of the NAND gate 462 and one input of the NOR gate 460. Therefore, if the value is a logic “1” in the push-pull mode this will drive the node 458 low, turning on transistor 456 and it will drive the gate of transistor 452 low. When a logic “0” is input to input port 476, the output of NAND gate 462 is driven high turning off transistor 456 and the output of NOR gate 460 is driven high, turning on transistor 452 and pulling node 450 to ground. This is a push-pull operation. In the open-drain operation, the control signal node 475 is set at a logic “0” in order to disable transistor 456 and enable OR gate 466. Node 454 is connected to one input of the OR gate 466 such that when a logic “low” is input to input port 476 and the output of NOR gate 460 is driven low, this will disable transistor 464. However, when a logic “1” is input to input port 476, this will force a logic “0” on node 454 which is connected to one input of the OR gate 466. This will cause the output of OR gate 466 to go low, enabling transistor 464 to act as a weak pull up. There is also an input on a line 477 that disables the pull up by putting a logic “1” on the input of OR gate 466 to pull the gate of transistor 464 high. This will utilize an external pull up in that event.

During a receive operation, the crossbar enable signal on node 468 is pulled low, since this is not a digital output. The digital input is provided by a receiver 478 that has the input therefore connected to the output port pin 314 on node 450 and the output thereof provided on a receive output 479. The receiver 478 is controlled by a signal on a node 480 that, when at a logic “1,” would disable the receiver 478, and when at a logic “0,” the receiver would be enabled. Node 480 is connected to the output of an OR gate 482, one input thereof connected to a signal C2_Active, which is the serial input port for receiving serial data for configuration and debug operation. This is associated with the debug/programming hardware block 374. The other input of the OR gate 482 is connected to the output of an AND gate 484, one input thereof connected to a control signal on an input node 485 that defines the port as the digital input and the other input thereof connected through an inverter node to an input node 486, this being the input that allows the port to be configured as an analog port for use with the analog peripherals. The node 480 is also connected to one input of the NOR gate 460 and, through an inverting node, to one input of the NAND gate 462. Therefore, when the node 480 is at a logic “1,” this will force the output of NOR gate 460 on node 454 low, disabling transistor 452 and it will force a logic “0” on the input of NAND gate 462, forcing the output thereof high, disabling transistor 456, such that the port can not drive the signal to the output port pin 314.

Whenever the port is configured as an analog input/output, both the digital receive function and the digital transmit function are disabled. A logic “1” on node 480 disables the receiver 478 and disables transistors 452 and 456. This will also control two analog paths, one controlled by a transfer gate 487 to connect output port pin 314 to an analog peripheral node 488, this being connected to the output of an analog multiplexer block 489. A second transfer gate 490 is provided for connecting output port pin 314 to an N-channel pull-down transistor 491, this being a pull-down. Thus, if transfer gate 490 connects output port pin 314 for the associated output port to the drain of transistor 491, this node will be pulled to ground. As will be described herein above, for a panel scanning operation, prior to the panel scan, all nodes associated with the columns and rows of the panel are pulled to ground. Thereafter, a select one or ones of the nodes will be tested by either self capacitance measurement or mutual capacitance measurement with the remaining nodes being held to ground through this pull-down transistor 491. The node of interest for being tested will then have the transfer gates 490 deactivated during the analog operation and the transfer gate 487 activated such that the analog input or output will be connected to the node 488 and controlled by the multiplexer 489.

The multiplexer 489 is an analog multiplexer associated with the pad that is operable to selectively connect the node 488 to either the MTR Tx line or bus 341, the MTR Rx line 344, the CDC/ADC bus or analog line 332 or to function as a crystal input for interfacing with one terminal of a crystal or to function as an RTC input. As noted herein above, certain ports can not be configured to connect to these particular lines. However, the analog multiplexer block 489 is a pad specific or port specific multiplexer that is capable of being interfaced with all of the associated potential analog signals. It may be that, from a layout standpoint, certain pins would not be connectable to, for example, the MTR Tx bus 341. In that situation, the line would not be run to the associated analog multiplexer. It may even be that certain ports would not have an analog functionality at all such that they would not require the associated T-gates 487 and 490 nor the multiplexer 489. However, for those ports that function both with digital input/output capability and an analog input/output functionality, the input/output circuitry of FIG. 4 will be utilized.

In order to select a particular pad as an analog input/output, the output of the OR gate 482 will be controlled to generate a logic “1.” Thus, one of the inputs to the OR gate 482 needs to be at a logic “1;” either the C2 Active input needs to be high or the output of the AND gate 484 needs to be high. The output of the AND gate 484 is high whenever the input on node 485 is high and the input on node 486 is low. Thus when the port manager generates a logic “1” on the node 485, then the node 480 is controlled by the signal on node 486. This signal can be generated by the CPU or it can be hardware generated by any of the analog peripheral blocks. As will be described herein below, the analog peripherals can operate in the various low power modes wherein the CPU is not operating. These analog peripherals, such as the MTR module 114 and the capacitive sense block 112, are hardware state machines. They can control any one of the particular blocks to function as an analog input/output block and also control which of the two transfer gates 487 and 490 are activated. This function is controlled by a transfer gate control block 494 which provides an AND function (not shown) which ANDs control signals from the respective hardware block to select either one of the transfer gates 487 and 490. As an example, consider the operation of the multi-touch resolve operation. In this operation, certain ones of the pins are controlled to be transmit pins and certain ones of the pins are controlled to be receive pins, as set forth in FIG. 3b. The control operation will, in a first mode, connect all of the respective columns and rows to ground, via global activation of the transfer gate 490. The respective output pads will be configured as analog input/output pads by pulling the node 486 low for those respective pads and then the transfer gates associated therewith will be turned on. In the next step, the panel scanning step, there will be a strobe of one row and all columns connected to ADCs 342 (a parallel sense operation). One row is connected to the MTR Tx line 341 and all of the columns are connected to their respective MTR Rx line on bus 344, it being noted that there will be one input to the associated multiplexer for a pad associated with one of the ADCs 342, this being a layout restraint. Thus, all of the MTR Rx signals will be connected through the T-gate 487 during a panel strobe to the respective MTR Rx bus line on bus 344 and, thus, to their corresponding ADC 342. The remaining row lines that are associated with the MTR Tx functionality will be connected to ground through the respective transfer gate 490. Alternatively, for the self capacitance check, each of the rows or columns in the display are individually selected with the remaining ones connected to ground through the transfer gate 490. Thus, one transfer gate 487 for one pad will be activated for this operation.

Thus, it can be seen that any particular pad can be controlled to provide an output driving signal from an analog signal generator or be connected to receive an analog input. This functionality can be provided in hardware such that a state machine running during the sleep mode of the processor can individually select a particular port for an output signal. As will also be described herein above, one of the output port pins 314 can also be configured as a synch port to provide a synchronization signal for a multi-chip operation. This would allow the state machine to generate a synchronizing edge at a given time for transfer to other chips. All this would require is that the transfer gate 487 for that pad be connected to the synchronizing signal generator, this typically being a logic gate that would output a synchronizing signal to the output that could be connected to other chips. This will be described in more detail herein below.

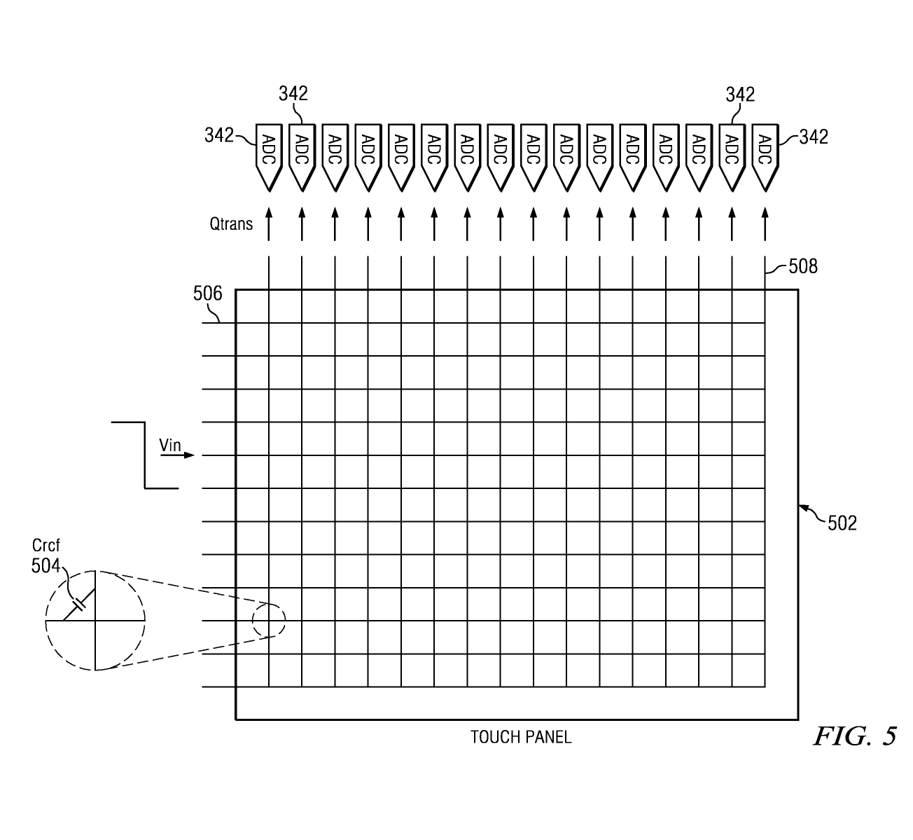

Referring now to FIG. 5, there is illustrated a diagrammatic view of a touch panel 502 representing the touch screen 104. The touch panel 502 is a capacitive touch panel that is comprised of a plurality of transparent row lines and column lines, the row lines being parallel to each other and the column lines being parallel to each other. These row and column lines are electrically isolated from one another and are all transparent. Typically, these conductive lines are formed from Indian Tin Oxide (ITO). This provides a mutual capacitance sensing medium such that, between the intersection of each row line and column line, there exists a row-to-column capacitance (C_{RCF}) 504. The row lines are designated as row lines 506 and the column lines are designated as column lines 508.

As was described herein above, each of the row lines 506 is sequentially driven by a negative going pulse and all of the column lines 508 are output simultaneously to a respective one of the ADCs 342 to allow charge to be transferred from the C_{RCF} associated with the intersection of the driven row line 506 and the respective intersection between that row line 506 and the column line 508. Charge is transferred from C_{RCF} to the respective ADC 342 and a conversion performed to convert that quantum of charge transferred out of C_{RCF} to a digital value, which will be described in more detail herein below. It should be understood that, although the illustration shows the rows being driven and the columns being sensed, it is possible to drive the columns and sense the rows. Thus, creation of a charge on the capacitor 504 followed by transfer of that charge to the ADC 342 allows for evaluation of the value of that charge.

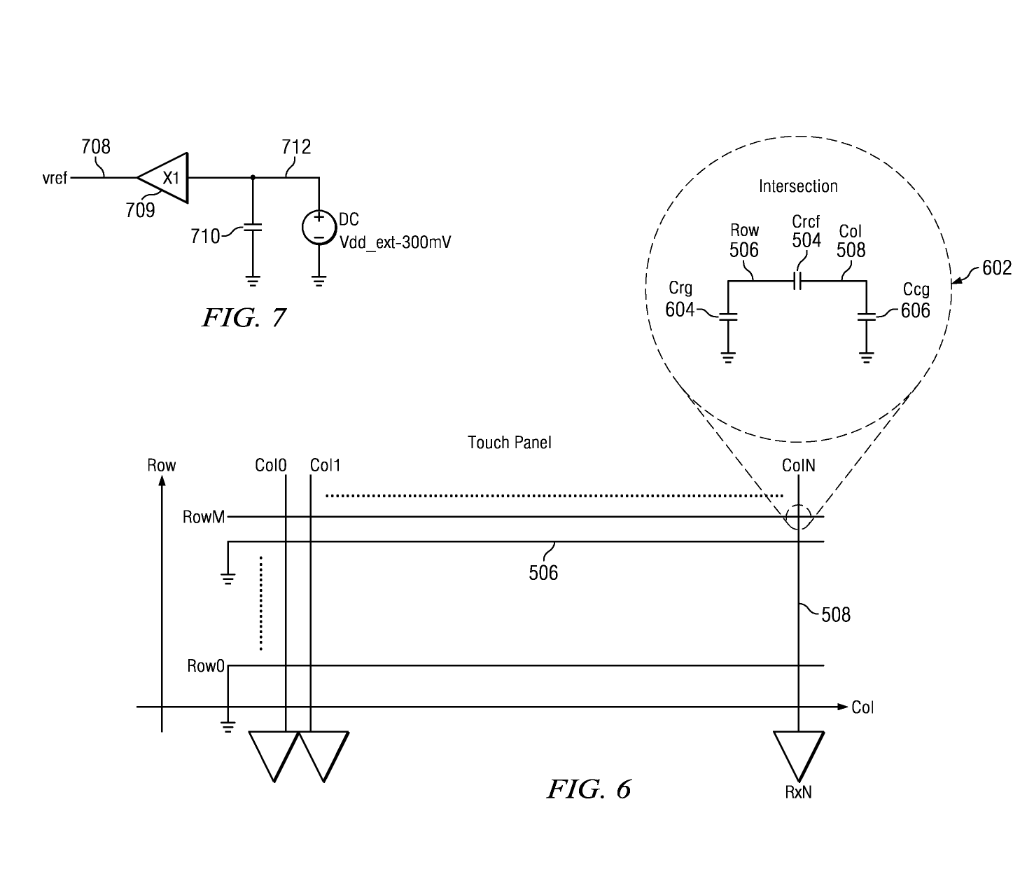

Referring now to FIG. 6, there is illustrated a detail of the touch panel 502 illustrating the intersection of the row lines 506 and the column lines 508 at a point 602. At this point, the circuitry therefor can be simplified as having the C_{RCF} for that intersection disposed between a row-to-ground capacitance (C_{RG}) 604 and the column-to-ground capacitance (C_{CG}) 606. Each of the row lines 506, depending upon the size of the panel, will have a capacitance to ground associated therewith. The larger the panel, the more the capacitance. This is also the case with respect to the C_{CG} capacitance on the column line. The desire is to measure the capacitance change of C_{RCF} whenever a finger touch is present. If there is a finger touch, what will happen is that C_{RCF} will decrease while C_{CG} and C_{RG} increase. Thus, each intersection is scanned such that the change in that the value of capacitance C_{RCF} can be determined. It is noted that the stronger the touch, the stronger the change in capacitance. However, the CPU 302 that evaluates these values will determine from the intersection or intersections that exhibit a change in capacitance whether a finger touch has actually occurred and what that information means. The circuitry associated with the display and the MTR function functions to measure the capacitance, determine if a change has occurred, collect data and inform the CPU 302 of such.

Referring now to FIG. 7, there is illustrated a diagrammatic view for the sampling circuitry for sampling the voltages for the ADC operation. Prior to performing a “conversion” operation wherein the charge from the associated C_{RCF} is transferred to the ADC 342 and converted into a digital value, power noise is minimized. As noted herein above, this particular peripheral block, MTR module 114 associated with the MTR function, is interfaced with the unregulated supply voltage, i.e., the battery voltage. In order to remove the noise, the driving voltage V_{DRV} for the MTR transmitter 340 is a divided and buffered value of V_{REF}. The ADC 342 utilizes this reference voltage on a node 708 that is derived from a sample capacitor 710 through a buffer 709 that samples the DC input voltage from the battery onto a node 712. The switches are not illustrated for the sampling operation for each of the node 712, but they will utilize such. The divided voltage V_{DRV} and the V_{IN} voltage are ratiometric so that the power noise will not be in the final result.

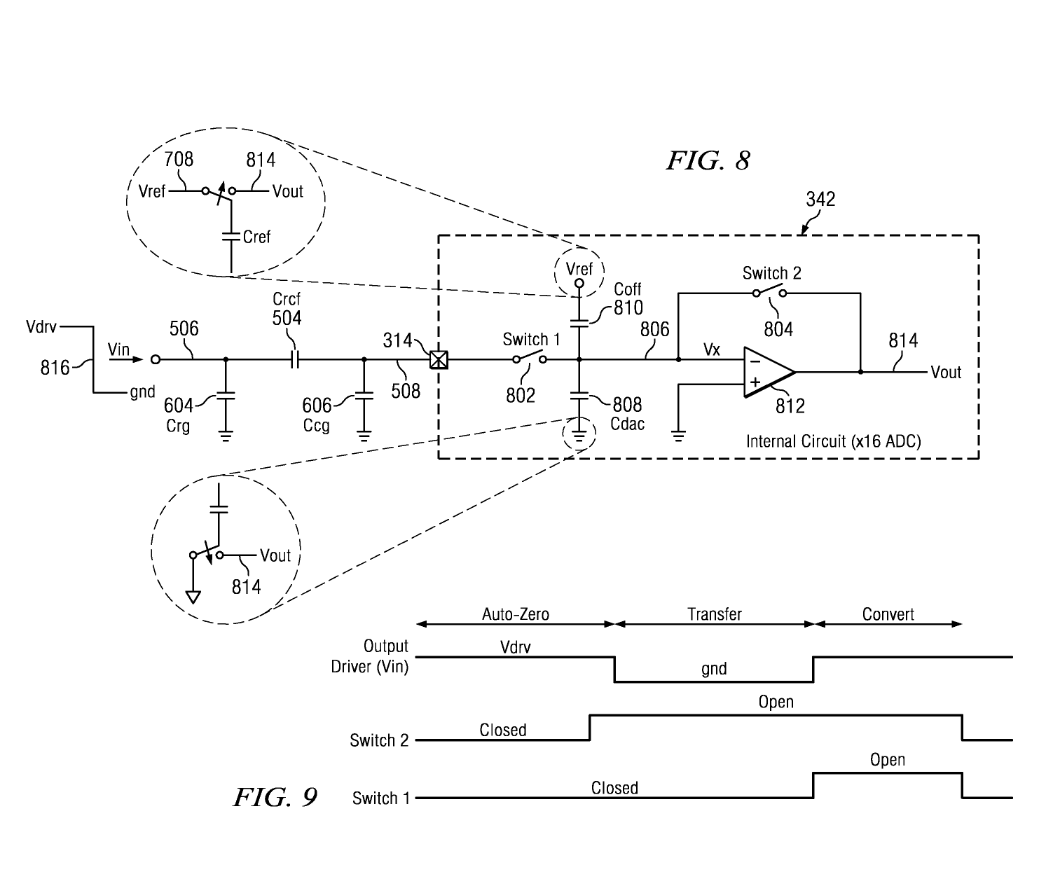

Referring now to FIG. 8, there is illustrated the basic configuration for the ADC 342. External to the chip at one of the pins 314 associated with a particular MTR Rx input, one column line 508 will be associated therewith. A row line 506 will be driven, it being noted that there will be up to sixteen ADCs 342 associated with sixteen column lines 508 that are perpendicular to the one single row line 506 that is being driven with the negative going edge referred to as V_{IN}. The ADC 342 interior to the IC 102 is denoted by a dotted line to indicate that it is interior to the chip. The ADC 342 will be connected to or interfaced to the column line 508 through the output port pin 314. A switch 802 (switch 1) is operable to switchably connect the column line 508 to an internal node 806. Node 806 is connected to one plate of a capacitor 808 labeled C_{DAC} and also to one plate of a reference capacitor C_{OFF} 810. The C_{DAC} capacitor 808 has the other plate thereof connected to ground with the C_{OFF} capacitor 810 having the other plate thereof connected to a voltage V_{REF}. Voltage V_{REF} is the voltage sampled onto the capacitor 710 and node 712 and then output on node 708 by buffer 709. The node 806 is connected to the negative input of an amplifier 812, the positive input thereof connected to ground for illustrative purposes. In general, the positive node will be connected to a common mode voltage in most instances, but this could be ground and is illustrated as such for clarity purposes. It should also be noted that this particular amplifier 812 has an offset voltage. Therefore, the negative input will typically be offset by an offset voltage which, for this embodiment, is approximately 900 mV but can vary depending upon the amplifier circuitry. The switch 804 is connected between the node 806 on the negative input of the amplifier 812 and the output thereof to switchably connect the two together and basically short the negative input to the output to provide a unity gain amplifier. The output is labeled V_{OUT}. The purpose for the capacitor C_{OFF} 810 is to guarantee that the amplifier 812 works in the high gain region for the entire range of C_{RCF} such that any voltage variation across C_{DAC} will not go above or below the rail voltage on the output of the amplifier 812.

The plate of capacitor 810 opposite to node 806 that is illustrated as being connected to V_{REF} is actually switchably connectable between V_{REF} on node 708 and the output of the amplifier on a node or V_{OUT} terminal 814. Thus, the other plate of the capacitor can be connected to two different voltages. Similarly, the other plate of the C_{DAC} capacitor 808, illustrated as being connected to ground, is switchably connectable between ground and the V_{OUT} terminal 814. This will be clarified with the description herein below.

Prior to describing the operation in detail, the general operation will be described. The goal of the operation is to initially charge up both the row line 506 and the column line 508 in what is referred to as an auto zero mode. This occurs at the high side of V_{IN} at a point 816 at level V_{DRV}. Depending upon the size of the display, the value of C_{RG} (capacitor 604) can be rather large. Similarly, the capacitor C_{CG} could also be large. Thus, there is required a certain amount of time for this capacitor to fully charge to the voltage V_{DRV}. This is a programmable length of time. It is noted that, prior to a “strobe” of any portion of the touch screen, all inputs (nodes associated with row lines 506 and column lines 508) are grounded. In order to charge up the node 508, switch 804 (switch 2) is closed such that the unity gain amplifier will drive the negative input. In this configuration, the negative input is essentially disposed at a virtual ground which, if amplifier 812 had no offset, would be the voltage on the positive input thereof. However, with the offset, the negative input will be offset from the positive input by 900 mV in one embodiment, although this offset value is a design choice. In any event, it will be at a fixed voltage which will cause the node 508 to be charged to the virtual ground voltage, referred to as “V_{X},” and this will charge up the column to ground capacitor C_{CG} 606, the C_{DAC} capacitor 808 and the C_{OFF} capacitor 810 to V_{X}. The next step is the sampling or transfer operation wherein the charge from the C_{RCF} capacitor 504 is transferred onto the C_{DAC} and C_{REF} capacitors. To do this, switch 802 is maintained in a closed position but switch 804 is opened and the C_{OFF} and C_{DAC} capacitors are connected in parallel between node 806 and the output of amplifier 812. This will effectively maintain the negative input at the virtual ground level V_{X} that existed when switch 804 was closed. This will keep the column line 508 and the node 806 at the same voltage and then V_{IN} is moved from the V_{DRV} voltage to ground. This will effectively transfer the charge on capacitor 504 to the C_{OFF} and C_{DAC} capacitors. However, it is noted that any analog voltage, when changing from one level to another at one time vs. another will change by substantially the same amount but may vary by a noise component. A conversion operation is then implemented wherein the column line 508 is isolated from node 806 and then the charge difference on the C_{DAC} and C_{OFF} capacitors determined with a successive approximation register (SAR) algorithm to determine a digital voltage representing the difference in charge. By isolating the column line from the ADC 342 during conversion, any noise that might occur during the conversion process will also be isolated. Thus, the operation will entail first charging up the capacitor 504, the C_{RCF} capacitor, with a quantum of charge. This quantum of charge is then transferred onto an internal capacitor or capacitors to change the charge disposed therein. This is followed by a determination of the change in charge. It is this change in charge that correlates to the charge on the capacitor 504. As will be described herein below, since the voltage on node 806 is maintained at the same voltage for the initial auto zero or charging operation of the column line and the charge transfer operation, this column-to-ground capacitor is effectively canceled out from the operation.

Referring now to FIG. 9, there is illustrated a timing diagram for the ADC operation. This ADC operation consists of three phases, an auto zero phase, a transfer phase and a charge to digital conversion phase. The first waveform illustrates the input driver signal that drives the row. This is a signal that is shifted between the drive signal V_{DRV} and ground. Initially, in the auto zero phase, switch 804 (switch 2) is closed and switch 802 (switch 1) is closed. This allows both the column line 508 and the row line 506 to be charged up from the initial ground condition, noting that one row is driven by a Tx pulse, whereas 16 columns are connected to ADCs 342. As noted herein above, the column line is charged to virtual ground V_{X} on the negative input of the amplifier 812. With the offset, this differs from the common mode voltage (or ground) on the positive input of the amplifier 812 by that offset voltage.

In the next phase, the transfer phase, switch 804 (switch 2) is opened and the voltage of V_{IN} driven to ground to transfer charge from the C_{RCF} capacitor (504) to the C_{DAC} and C_{OFF} capacitors. Switch 802 (switch 1) still remains closed. Note that, when switch 804 is open, the opposite plates of C_{DAC} and C_{OFF} which were originally connected to ground and V_{REF}, respectively, will be switched to V_{OUT}. This effectively transfers a charge onto C_{DAC} and C_{OFF}. At the end of the transfer phase, the convert phase is initiated with switch 804 still remaining open. The opposite plates of capacitor C_{DAC} and C_{OFF} from node 806 are again switched to ground and V_{REF}, respectively, after switch 802 (switch 1) opened. During this phase, the amplifier 812 functions as a comparator in a SAR conversion operation, which will be described herein below.

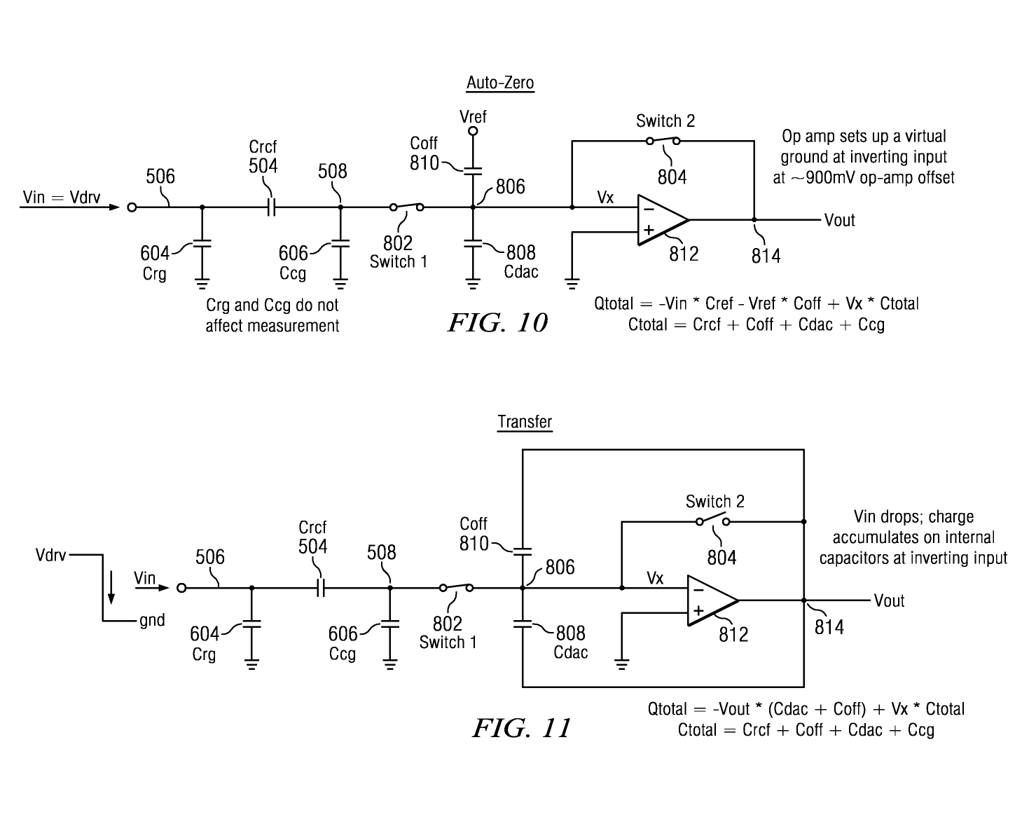

With specific reference to FIG. 10, there is illustrated a configuration for the auto zero phase. In this configuration, switch 804 (switch 2) is closed thus driving the negative input of amplifier 812 on node 806 to virtual ground which will charge node 806 to the virtual ground voltage V_{X}. This will result in a voltage across C_{DAC} of V_{X}, a voltage across C_{OFF} of V_{REF}-V_{X}, a voltage across C_{CG} of V_{X} and a voltage across C_{RCF} of V_{DRV}-V_{X}. The charge on the plate 806 is referred to as the total charge or Qₜₒₜₐₗ. Since the charge across the capacitor is set by the relationship Q=CV, the following relationship will exist for Qₜₒₜₐₗ:

Qtotal=−Vin·Cref−Vref·Coff+Vx·Ctotal

Where:Ctotal=Crcf+Coff+Cdac+Ccg

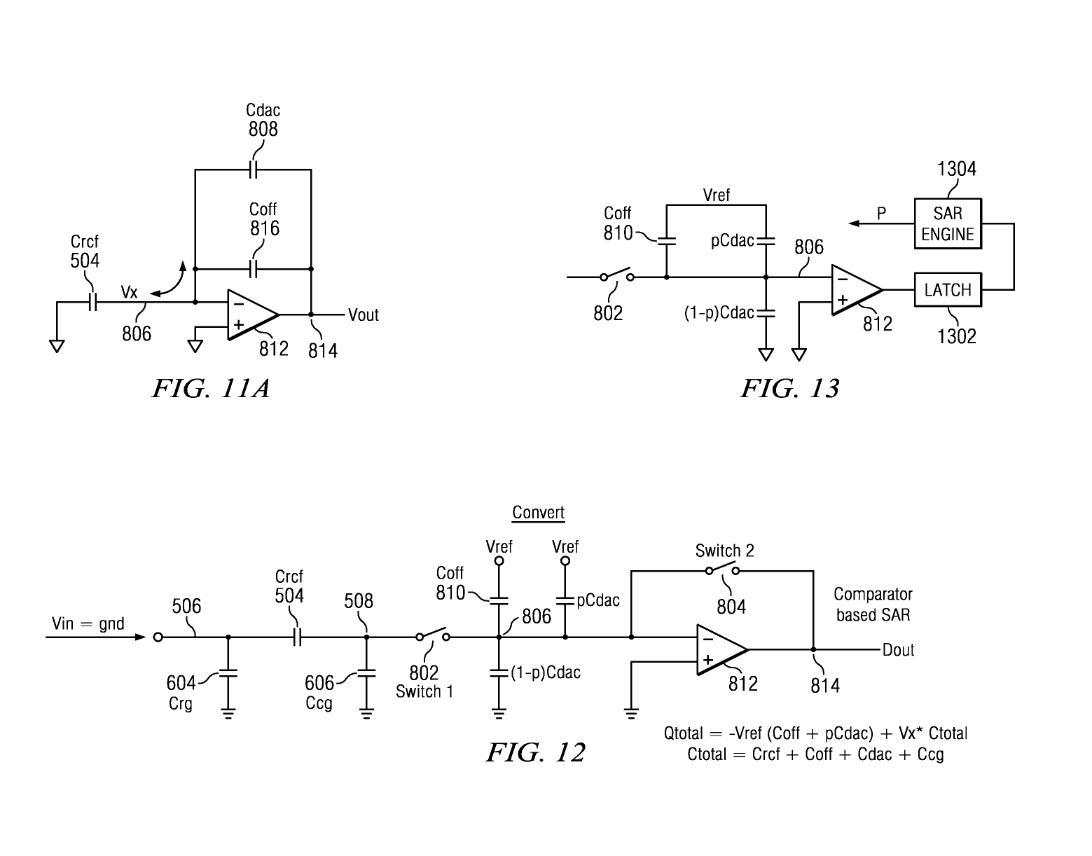

Thus, the amplifier 812 was configured as a unity gain op-amp to basically set up a virtual ground at the inverting input thereof on node 806. The next step is to go to the transfer phase illustrated in FIG. 11. In this phase, switch 2 is opened and the opposite plates of C_{OFF} and C_{DAC} from node 806 are connected to the V_{OUT} terminal 814. Then, V_{IN} is dropped from the V_{DRV} drive level to ground. This will force charge onto the C_{OFF} and C_{DAC} capacitors because the node 806 is at a virtual ground level at voltage V_{X} and is maintained there by the amplifier 812 configured as a feedback amplifier. This will cause the charge on capacitors C_{DAC} and C_{OFF} to change. This is better illustrated in the simplified diagram of FIG. 11a. It can be seen that the charge on the capacitor C_{OFF} and C_{DAC} would be defined by the relationship Q=(V_{O}−V_{X})(C_{DAC}+C_{OFF}) after charge is transferred thereto. The change in C_{RCF} would be changed once V_{IN} was lowered. When V_{IN} is lowered, the charge on the C_{RCF} capacitor 504 is transferred because the voltage across the C_{CG} capacitor 606 has not changed. The result of V_{IN} going from V_{DRV} to ground causes an increase to the charge in C_{RCF}, thus decreasing the charge in C_{OFF} and C_{DAC}. The following relationship exists with respect to the total charge on the node 806:

Qtotal=−Vout·(Cdac+Coff)+Vx·Ctotal

Where:Ctotal=Crcf+Coff+Cdac+Ccg

After the defined time during which the charge will transfer, the conversion operation is then entered, this being a SAR conversion operation. Prior to the conversion operation, however, switch 802 is opened to isolate the column line 508 from the ADC 342 such that any external noise will not affect the conversion operation. Since the charge has already been transferred to C_{OFF} and C_{DAC}, all that remains is to determine the amount of charge transferred thereto.

During the conversion operation, the switches that switch the opposite plates of C_{DAC} and C_{OFF} to V_{OUT} are reconnected to ground and V_{REF}, respectively, such that the capacitors are in substantially the same condition as the auto zero phase noting that analog ground for different components connected to different grounds, i.e., on-chip, off-chip, etc., can have various noise components associated therewith and there may be slight differences. Initially, C_{DAC} at full value is connected between node 806 and ground. The amplifier 812 is now in an open loop configuration such that it is no longer operating as an op-amp and, thus, does not hold the inverting input thereof at the virtual ground level, what will occur is that the voltage on node 806 will change, i.e., it will not be at V_{X}. Thus, the output of the amplifier 812, it now functioning as a comparator, will be high or low. What then occurs is that the value of C_{DAC} is ratioed such that a portion thereof will be connected from node 806 to V_{REF}. The capacitor C_{DAC} is set at a value of approximately 5 pF which is essentially the approximate full range value of the row-to-column capacitance C_{RCF}. It is configured utilizing a plurality of unit caps of value “C” connected in parallel to provide a 5 bit binary set of capacitors, i.e., capacitors C, 2C, 4C, 18C and 16C, and a 5-bit thermometer code utilizing 32 unit caps of value. These can be configured such that the portion of C_{DAC} that is connected between node 806 and ground will have a value of (1−p)C_{DAC} and the portion of C_{DAC} connected between node 806 and V_{REF} will be pC_{DAC}. It can be seen that if p=0, this would indicate that the value of C_{RCF} would be equal to zero. This would be expected in that no change in the charge across C_{DAC} and C_{OFF} existed and, therefore, the voltage on node 806 would essentially be V_{X}, a voltage right at the trigger point for amplifier 812 configured as a comparator. When C_{RCF} is not zero and has some charge stored therein, and charge has been transferred, the SAR algorithm will vary the value of p until the voltage on node 806 is approximately equal to V_{X}, the trip voltage. At this point, there will be a digital value associated with the value of p which will equal the digital value corresponding to the charge on C_{RCF}. Thus, what has been achieved is an analog-to-digital converter that converts charge to a digital value. It is a charge-to-data converter in essence. The relationship for Qₜₒₜₐₗ for node 806 during the conversion operation is, for the configuration illustrated, as follows:

Qtotal=−Vref·(Coff+pCdac)+Vx·Ctotal

Where:Ctotal=Crcf+Coff+Cdac+Ccg

Another way to describe the way in which the charge is present on the various capacitors and nodes is to calculate the charge in a different manner. Referring back to FIG. 10 and the auto zero mode, it can be seen that the common plate charge on node 806 will be as follows:

Qaz=Vx·Cdac+(Vx−Vref)·Coff+(Vx−Vdrv)·Crcf+Vx·Ccg

This takes into account the charge across each of the C_{RCF}, C_{CG}, C_{DAC} and C_{OFF} capacitors.

Then, following through to FIGS. 11 and 11a, it can be seen that, when the voltage on the row line is pulled from V_{DRV} to ground, the common plate charge on node 806 will be defined as follows:

Qxfer=(Vx−Vo)·CDAC+(Vx−Vo)·Coff+Vx·Crcf+Vx·Ccg

Since the total charge has not changed but, rather, has merely been shifted from C_{RCF} to C_{DAC} and C_{OFF}, the other relationship Q_{az}=Q_{xfer} will be valid. With this equality, and substituting in the equations for Q_{az} and Q_{xfer}, the following relationship will result:

Crcf·Vdrv=Cdac·Vo+Coff·(Vo−Vref)

This will result in the following relationship with respect to the output voltage of the amplifier 812:

$$Vo = \frac{Coff \cdot Vref + Crcf \cdot Vdrv}{Cdac + Coff}$$

In the conversion phase, illustrated in FIG. 12, the two capacitor values will be C_{OFF} and pC_{DAC} connected between node 806 and V_{REF} and (1−p) C_{DAC}, disposed between node 806 and ground. The relationship for the common plate charge on node 806 at the end of the SAR conversion phase where the voltage on the inverting input of the amplifier 812 will be essentially equal to the trip point which is V_{X}, i.e., the virtual ground voltage. The plate charge on node 806 in the configuration of FIG. 12, wherein the node 806 is disposed at V_{X} at the end of the SAR conversion process and the capacitors C_{OFF} and pC_{DAC} are connected between node 806 and V_{REF} and the capacitor (1−p) C_{DAC} is connected between node 806 and ground, should be identical to the charge that was stored on C_{OFF} and C_{DAC} when they were connected in feedback with amplifier 812 in FIG. 11 and FIG. 11a. Thus, the following relationship will represent that equality:

Cdac·Vx(1−p)+pCdac·(Vx−Vref)+(Vx−Vref)Coff=(Vx−Vo)(Cdac+Coff)

Upon reducing the above equation, the following relationship will exist:

p·Cdac−Vref=Cdac·Vo+Coff(Vo−Vref)=Crcf·Vdrv

which will yield:

$$p = \frac{Crcf \cdot Vdrv}{Cdac \cdot Vref}$$

It can be seen from the previous equation that, if C_{RCF} is set equal to zero, the value of p will be set equal to zero, which shows that there will be no distribution of charge. If C_{RCF} is equal to C_{DAC}, and V_{DRV} is equal to V_{REF}, then the value of the capacitor C_{DAC} disposed between node 806 and ground would be equal to zero, since p=1.

Referring now to FIG. 13, there is illustrated a diagrammatic view of the SAR engine during the conversion phase. During this phase, the amplifier 812 is configured as a comparator and switch 802 (switch 1) is open, thus isolating node 806 from the array and, thus, preventing any noise from being passed across switch 802 from the array. C_{DAC}, as described herein above, is comprised of multiple capacitors such that a portion of the capacitor C_{DAC} can be disposed between node 806 and ground and a portion can be disposed between node 806 and V_{REF}. The output of amplifier 812 is input to a latch 1302, the output thereof utilized by a SAR engine 1304 to generate the value of “p.” The C_{DAC} capacitor is comprised of a 5-bit binary capacitor section and a 5-bit thermometer section. The binary section is comprised of a combination of unit capacitors which stores a value “C” such that the capacitors in the 5-bit binary array are C, 2C, 4C, 8C and 16C, resulting in 31 unit capacitors. The thermometer portion will have 2⁵−1 capacitors or 31 capacitors of size 32C. This type of DAC is usually referred to as a hybrid DAC wherein the thermometer coded bits are associated with the five most significant bits and the binary weighted bits are associated with the five least significant bits. With the binary weighted portion of the DAC, elements corresponding to the more significant bits are weighted higher than elements corresponding to the less significant bits. With respect to the thermometer coded DAC portion, the number of asserted bits in the thermometer code would be proportional to the value of the digital signal and each bit of the thermometer code is provided to a corresponding capacitor. A binary to thermometer decoder is utilized to generate the thermometer code from the binary code.

During the SAR operation, the first step will be to assert the most significant bit and determine if node 806 is at or below the trip point. As described herein above, the trip point will be the virtual ground which is basically the voltage offset from the positive input voltage. Even though this voltage is illustrated as being connected to circuit ground, it would typically be connected to a common mode voltage generated on-chip. Thus, when the voltage goes above the trip point, the output of amplifier 812 will go negative and, when it is below the trip point, the output will go positive. The SAR engine 1304 will test each bit to determine if the voltage on node 806 is above or below the trip point. If it is below the trip point, that bit will be maintained as a latched value and then the next value tested, such that each lower MSB can be tested in sequence. If the next MSB causes the voltage to go above the trip point, this bit is maintained at a logic “0” for the value “p.” At the end of the SAR operation, after 10 bits, the value will be latched and this will constitute the result. What this value indicates is a digital value corresponding to the charge that was transferred to C_{OFF} and C_{DAC}. As noted herein above, if the value of the transferred charge were “0,” there would have been no change in the charge stored on C_{OFF} and C_{DAC} and the voltage on node 806 in that situation would have been equal to the trip point voltage (the virtual ground voltage) and the result would be that value of “p” would be equal to zero. Thus, by transferring the charge to the capacitors C_{OFF} and C_{DAC} and then isolating node 806 from the array, a conversion can be made to a digital value that represents the charge on C_{RCF}. This is thus a data converter that converts charge to a digital value or a charge-to-digital converter.

The value output by the ADC 342 is utilized to determine whether there has been a change in the capacitance value or the charge stored on the capacitor. In the presence of a touch, the column to ground capacitance will increase and the column-to-row capacitance (C_{RCF}) will decrease. If the decrease is beyond a certain threshold, a decision can be made that this is a “touch” condition. However, scanning of an array will usually result in a no-touch decision since the display is idle a large percentage of the time with respect to the user interface thereto. Thus, it is the desire to minimize the amount of power required to make the determination that there is a “no-touch” condition.

To determine that there is a touch one compares a current value of C_{RCF} to a prestored value representing the no-touch situation. This is referred to as the “baseline value.” The baseline value for each of the C_{RCF} capacitors in the array will be determined during a calibration operation. This calibration operation can be user initiated or it can be automatically based on time or even temperature. When the temperature of the device containing the touch screen and the chip changes, this can change the values of the capacitor C_{RCF} and, therefore, there will be some type of calibration.

As will be described herein below, there are multiple modes of operation of the chip to conserve power. One of the largest sources of power consumption on the chip is the operation of the controller core or CPU 302 and the digital circuitry associated therewith, the operation referred to as the MCU operation. When the MCU is active and executing instructions, the current draw will go up significantly. Thus, the entire chip has the ability to operate in different modes of operation to, for example, stop execution of the controller core or CPU 302, suspend operation of the system clock block 376 and even remove power from a large portion of the digital circuitry. There are defined multiple modes. One mode is the active mode which is a mode wherein the system clock block 376 is operating to generate the system clock, the controller core or CPU 302 is executing instructions and, in essence, the MCU is fully functioning. There can be multiple modes, there being an active mode, a normal mode and a low power mode. In the normal mode, everything is functioning. In the low power mode, certain select aspects of the digital circuitry can be turned off For example, if the SMBus is not being accessed, it is not necessary to clock that peripheral. The clock generator block or system clock block 376 has a clock generator 388 that can generate the various peripheral clocks. As will be described herein below, these peripheral clocks are generated in response to a request for a clock signal thereto. The circuitry for generating the clock is not activated until such request is made.

A second mode is an idle mode. In the idle mode, the execution operation for the controller core or CPU 302 is halted but digital power is maintained thereto. The operation of the system clock can also be suspended. When the system comes out of idle mode to active mode, the CPU 302 will begin servicing the various interrupts, etc., that have requested to be serviced and the programs run that are associated with the requests. However, the digital power is maintained in the idle mode. Once digital power is removed, the CPU 302 will effectively have to boot up when the LDO portion of the regulator 364 is again brought up to power. This can take time and consume unnecessary power. Therefore, the CPU 302 in the idle mode will be in a ready condition. There is also the sleep mode wherein the digital portion is essentially powered down but portions of the chip can remain operational. Typically, the RTC or smart clock block 386, the I²C block 358 and other portions of the circuitry such as a function termed “port match” will operate. These are analog peripherals in the analog peripheral block 312. As noted herein above, the MTR module 114, the CDC112 and the I2C block 358 are self-clocked such that they can operate outside the presence of the system clock generator block 376 or the CPU 302 in operational mode. An interrupt will “wake up” the CPU 302. Since most scans will result in a no-touch determination, it is desirable to minimize the amount of digital power that is applied to the digital portion of the circuitry. It is noted that the MTR MODULE 114 operates in the idle mode, but not the sleep mode.

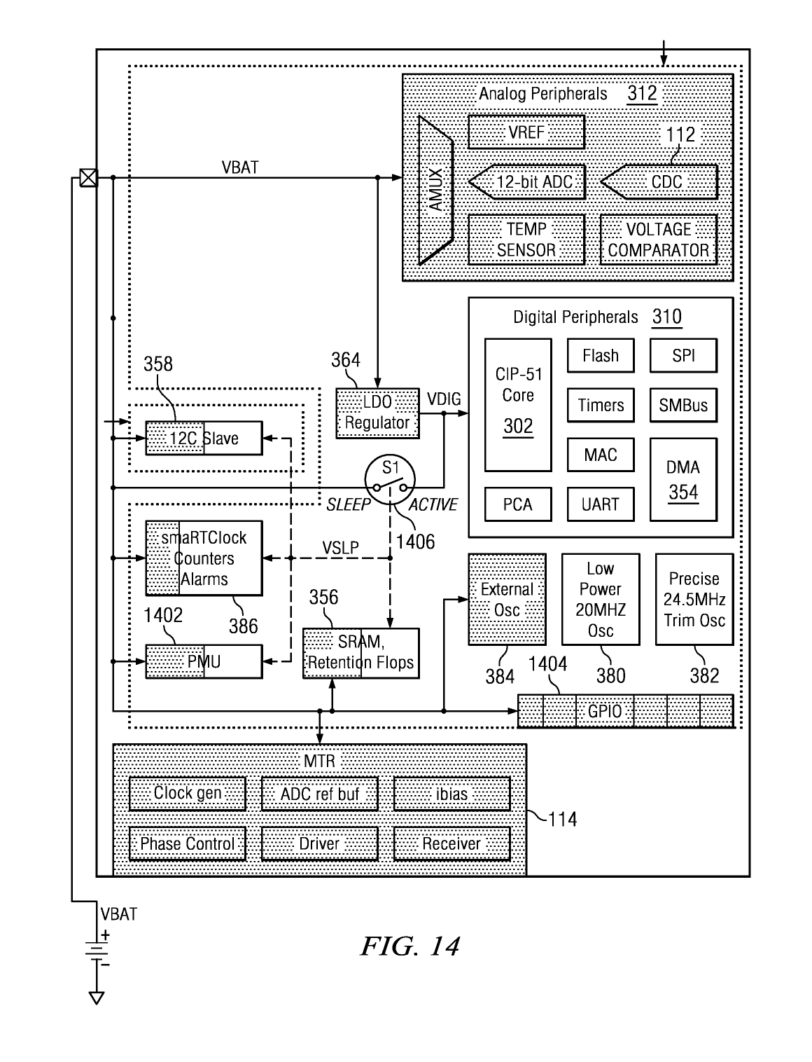

Referring now to FIG. 14, there is illustrated a diagrammatic view of the top level power domain architecture. There are essentially three different supply domains. The first is V_{BAT}, which is the battery voltage domain with a range of 1.8-3.6 V. The second is V_{DIG}, the digital voltage domain, which is the regulated supply for the digital core. This is set at approximately 1.8 V. The next is the V_{SLP} domain. This domain is not an actual supply, but denotes that the supply node switches between V_{DIG} and V_{BAT} depending on the part being in an active or a sleep mode. The portions of the circuitry that are connected to the V_{BAT} domain are illustrated in crosshatching and they constitute the analog peripheral block 312, the LDO regulator block 364, a portion of the I2C block 358, a portion of the RTC block 386, a portion of a power management unit (PMU) 1402, a portion of the XRAM 356, the MTR module 114, the external oscillator circuit 384 and a general purpose I/O block (GPIO) 1404. The digital peripheral interface block 310 (including the CPU 302, the DMA 354 and the MAC 352), the low frequency oscillator 380, and the precision oscillator 382 will be in the digital domain, i.e., that will be in the active mode. The LDO regulator 364, when in the active mode, will generate the voltage V_{DIG}. There is provided a switch 1406 that represents switching between the active and the sleep mode. In the sleep mode, the remaining portion of the voltage for the I2C block 358, RTC block 386, PMU block 1402 and memory 356 will be supplied by the battery. In the active mode, this remaining portion will be connected to the digital voltage, this circuitry allowing such things as peripherals to interface between two clock and voltage domains. This essentially comprises some of the digital circuitry in these particular blocks which will be active during sleep mode. In sleep mode, as described herein above, the LDO regulator 364 will be powered down but, as can be seen from the entire diagram, the analog peripheral block 312 and the MTR module 114 will be active. The V_{SLP} is used to prevent loss of information inside SRAM and retention flops during sleep mode. The way the MCU can resume operation immediately without having to initialize the memory.

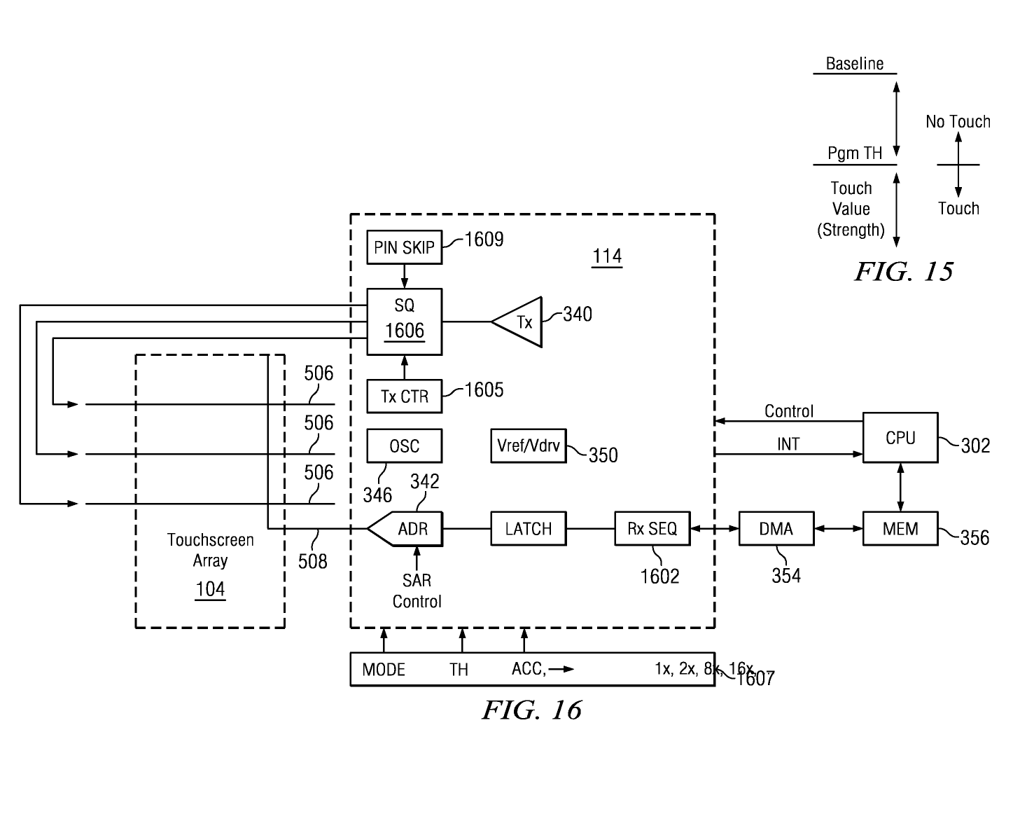

Referring now to FIG. 15, there is illustrated a diagrammatic view of the hardware MTR module 114 block and the implementation thereof in the touch/no-touch decision operation. This is a state machine. A baseline will be provided and stored in the memory 356 in a particular location for each capacitor C_{RCF} in the array or each intersection of row and column lines. Essentially, this will be the intersection of each MTR Tx output and each MTR Rx input. This baseline value will constitute the no-touch MTR result. However, any kind of noise or small change in C_{RCF} may not constitute a touch. Therefore, a threshold is programmed into an SFR associated with the MTR module 114. This will provide a threshold relative to the baseline value beyond which a decision will be made that the change in C_{RCF} constitutes a touch. Any value of a change beyond the threshold relative to the baseline value will constitute the strength of the touch value. As will be described herein below, it is not necessary to store the actual raw data from the ADC 342 but, rather, the value of the strength after the touch determination, although there is a mode to store just raw data. Therefore, the value stored when a touch is determined will be the baseline value (BL) minus the threshold value (TH). For example, if the baseline value were equal to 1.0 and the threshold value were equal to 0.5 and the actual value were equal to 0.3, the value of 0.2 would be the strength. This is all that would be stored for processing by the CPU 302.

First the actual strength or touch value is determined and this is facilitated with a hardware circuit. This operation will constitute the scanning operation of a particular row which is referred to as a “strobe” operation. A “single strobe” is referred to as the operation wherein the row is processed through the auto zero phase, the transfer phase, and the conversion phase wherein the charge of all of the C_{RCF} capacitors associated with that row are transferred to the associated ADC circuits 342 and these will each generate a value for processing to determine if a touch occurred, this determination made for each C_{RCF}. Once a touch has occurred, the strength value is transferred to the memory 356 utilizing the DMA 354, as will be described herein below. Note that the determination of a “touch” at a particular C_{RCF} may in fact be a false “touch.” All that is determined is that the value has changed a significant enough amount to suspect a touch when the data for the entire array is evaluated.

Although a single calculation for a single transfer operation will provide a value for C_{RCF} and the charge associated therewith on the output of the associated ADC 342, it may be desirable to average the calculation over multiple charge transfer operations. This is a programmable function which is referred to as the accumulator function. This is a programmable function such that the number of accumulations for a given determination will be defined by the user. Therefore, when an accumulation mode is entered, a “single strobe” will be further defined as the result after all of the accumulations are performed. Thus, each row will be subjected to the transmit pulse falling from V_{DRV} to ground a predetermined number of accumulation times. For each accumulation operation, there will be an auto zero, a transfer and a convert phase to provide a result which will be added to a previous result. (Note that all modes are grounded before autozero.) The sum of these values will constitute the value of charge for C_{RCF}. Thus, with such a digital accumulation operation, it is possible with the setting of a particular value in an SFR to accumulate 2×, 4×, 8×, 16×, etc. without any changes to the circuitry. Of course, the higher the accumulation number, the longer the scan time for each row. (Again, it is important to note that the terms “row” and “column” are utilized herein in a sequence but it should be understood that the rows could be connected to the ADCs 342 and the MTR Tx pulses input to the columns.)

Referring now to FIG. 16, there is illustrated a simplified diagrammatic view of the MTR module 114 State Machine and the interface with the DMA 354 and the memory 356. The MTR module 114 includes a hardware controller 1602 which is operable to interface through the DMA 354 with the memory 356 and also with the output of the ADC 342 operation. This allows for a Read and/or Write operation. The hardware controller 1602 will retrieve the results, accumulate them if such is designated by a user, determine if the threshold has been exceeded and, if so, then a determination is made as to what the strength of the touch is and this stored in the memory 356. During operation, the memory 356 is accessed if necessary to either retrieve a baseline value or to store information therein. Thus, if a baseline value is required to determine if the threshold has been exceeded, a Read operation is performed. With the use of the DMA 354, it is not necessary for the CPU 302 to operate.

Once a decision is made that a touch has occurred, the strength of that touch can, in one mode, be stored in the memory 356 in a particular location and then an interrupt generated to the CPU 302. There are various interrupts that are generated, one indicating the end of a strobe (the end of all operations utilized to generate a total set of accumulated value for a given row), an interrupt for a touch determination, etc. These interrupts are merely to advise the CPU 302 that a certain operation has been completed such that the CPU 302 can initiate another operation. For example, the CPU 302 initiates a scan or strobe of a given row with an initiating control value. This control value is generated and sent to the MTR module 114. The CPU 302 can then go into an idle mode at that time and allow the MTR module 114 to go forward therefrom. The CPU determines which row will be strobed by enabling the appropriate MTR Tx signals, i.e., setting start and stop values for selecting the particular output pin for the V_{IN} signal. Once this is enabled, is for the MTR module 114 then generates the correct V_{IN} signal at the appropriate time for the particular auto zero/transfer/conversion operation for the accumulated number of times. If it was determined that no touch was sensed, an interrupt to the CPU 302 would be generated to indicate the end of a particular row line. The CPU 302 need not access the memory 356 until an entire scan of the touch screen 104 is performed or a portion thereof in accordance with a predetermined program. Thus, the CPU 302 need only be activated at the end of a strobe to sequence to the next block in the “single strobe” scan operation or at the end of a panel scan in the “panel scanning” mode of operation. The panel scan operation can scan the MTR Tx pins automatically with a sequenceR block 1606 whereas the CPU 302 initiates the next strobe in the single strobe scan operation. The sequence block 1606 operates in conjunction with a Tx counter 1605 that increments the Tx output for each strobe. There is provided an MTR SFR that has stored therein the start and stop MTR Tx channels for a particular scan operation, in addition to other configuration information. In addition, there is provided a pin skip decoder 1609 that controls the sequencer block 1606 to skip certain pins that are not connected. This will be described herein below.

In the MTR module 114, there is illustrated the buffer 350 which is operable to define the V_{REF} value and the V_{DRV} value. These are typically the same value, but it is possible to program the V_{DRV} value for a lower voltage such as V_{REF}/2, V_{REF}/4, or V_{REF}/8. The reason for this is that, by design, the C_{RCF} capacitor is expected to be approximately 5 pF, but it could be larger. In this situation, it may be desirable to lower the value of V_{DRV}. Also, the MTR module 114 has a randomizer 1610 that randomizes the start time of the transfer operation to reduce tonal interference.

In order to minimize the amount of noise that occurs as a result of the sampling operation wherein charge is transferred from the C_{RCF} capacitor to the node 806 and on to the capacitors 808 and 810, sample time dithering is utilized. This is facilitated by randomly changing the time at which the transfer or sample time occurs. This is basically delaying the time at which the transfer operation occurs. However, it is important to note that the opening of switch 2 is tied to the operation of the transmitter. Therefore, switch 2 will be opened just prior to the transmitter changing the voltage on the transmit channel from a high voltage to a low voltage. It is important that the amount of time between switch to opening and charge being transferred be tightly controlled. Additionally, the time that switch 1 is opened is also controlled relative to the time that the transmit output voltage for the selected channel drops from high to low. All the times are relative to each other. The dithering merely changes the time at which this charge transfer occurs. This will reduce total interference which, if not reduce, could decrease sensitivity. There are two ways to achieve this sampled dithering. The first is to utilize a randomizer 1610 and introduce a delay at each sample time. This could be a positive delay or a negative delay, keeping in mind that there is a defined minimum for the autozero time. This delay could be generated for each conversion operation, keeping in mind that for a “single strobe,” there could be multiple accumulations for a given strobe operation. The delay could be maintained constant for all accumulations in the single strobe or it could be varied for different accumulation operations within a given single strobe. Since the clock generates the switch controls for all ADCs 342 at the same time, it may not be possible to individually control the conversion operation for each of the ADCs 342. However, there is also a possibility this could be implemented, although it is not described in the present embodiment. Thus, this method utilizes a random number generator disposed therein as part of the State Machine that will vary the opening of switch 804 and the opening of switch 802 relative to the charge transfer operation when the voltage on a Tx channel is pulled low by a predetermined delay.

The second method is one that is controlled by the CPU 302. In this method, a delay value is written into the MTR SFR 1607 to define the amount of delay for the sampling time for a given strobe. This technique would utilize a delay of, for example, “3” counts of the MTR clock for one single strobe operation of a given row or Tx channel and, for the next row or Tx channel, extend this by an additional 3 counts for a total of 6 counts and, for each row or Tx channel thereafter, keep extending it by an additional 3 counts. The idea is that the sampling time for each conversion operation is delayed from the previous operation and the CPU 302 can effect this because it is able to program the length of the auto zero phase.

The hardware controller or State Machine 1602 is operable to operate in multiple modes in conjunction with the ADC 342. The MTR module 114 and the hardware aspect of the MTR module 114 operate in a number of different modes. These modes allow the MTR to perform in hardware many of the scanning functions and decision operations required in order to perform a scan, make a decision as to whether there is a touch or no-touch, collect data and transfer this data to memory with little or no assistance of the CPU 302 such that the overall MCU can be in the sleep or low power mode during this time.

As to the conversion modes, there are two conversion modes provided for. The first is the single strobe which basically one transmit operation to a row and multiple receive operations. The single strobe, as noted herein above, can require multiple accumulations for a given strobe operation. However, the single strobe is initiated by the MCU and, at the end of that strobe (all accumulations), the CPU 302 is notified and the MTR module 114 awaits further instructions. The second conversion mode is the panel scan mode which involves multiple strobes. These multiple strobes are initiated at a particular start and end Tx channel defined by data loaded into the MTR SFR.

Each of the different conversion modes has data modes. This is the operation wherein data is to be transferred either to the memory through the DMA 354 or directly to the CPU 302. The first data mode is the SFR mode wherein the MCU directly reads data from a single SFR associated with the hardware controller 1606 without requiring access to the memory. A second mode is the DMA mode wherein data is dumped into the memory. This can be performed by requiring an acknowledgement signal for each transfer to the DMA or the system can operate in a DMA burst mode wherein multiple requests are sent to the DMA to transfer data for multiple channels. There is the compare mode wherein the data from the ADC 342 (raw data) is subtracted from a baseline value which is retrieved from memory via the DMA 354 and compared to a threshold voltage to determine a touch/no-touch decision. In a fourth mode, a subtract mode, the strength of a particular touch after a touch detection is determined and stored in memory via the DMA.

There are also provided a plurality of interrupts and flags that can be generated by the hardware controller. The first interrupt flag is a “conversion done” generated after each single strobe. A second flag is one for a “conversion done” after each panel scanning A third flag is one for “less than event” during the compare mode. A fourth interrupt or flag is a “DMA timeout” flag. It is noted that the “conversion done” flag is set after the accumulation is completed.

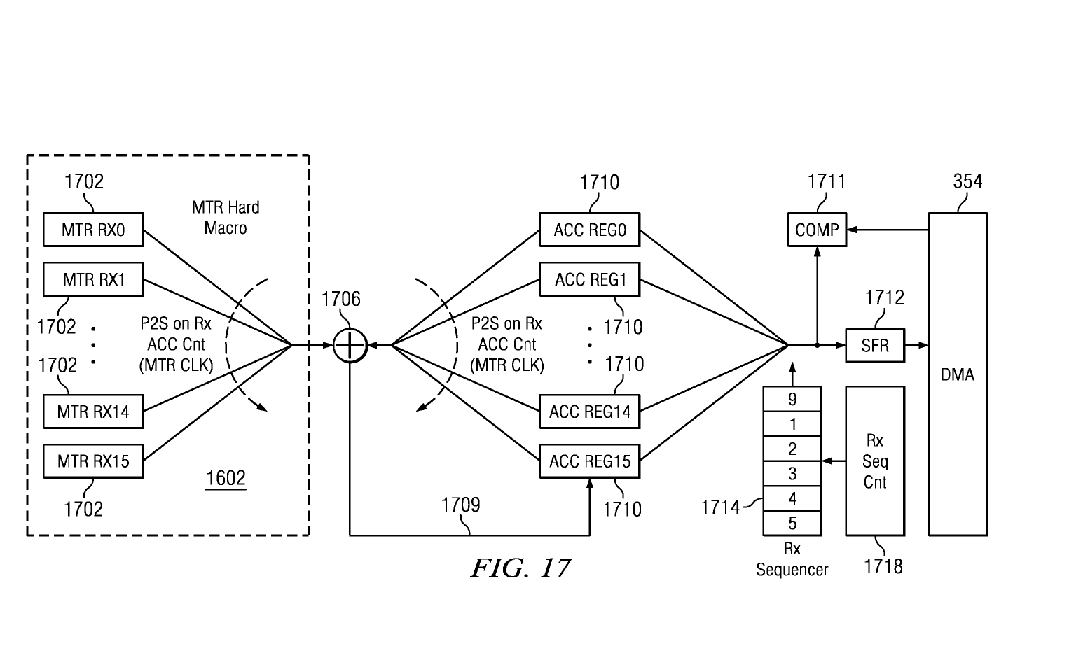

Referring now to FIG. 17, there is illustrated in more detail a diagrammatic view of the receive sequencer 1602. The receive sequencer 1602 is comprised of a plurality of MTR receive registers 1702 which are basically the latched output from the associated ADC 342 after the SAR conversion. These constitute registers wherein the value at the end of the conversion cycle is stored. (Note that another conversion operation can be initiated after storage in the register 1702.)

When the last SAR cycle in the conversion phase occurs, the value of p, the digital value corresponding to the transferred charge, will be stored in register 1702. There will be provided an accumulator counter 1703 that will sequence through each of these stored values for output to a summing block 1706. The summing block 1706 is shared and is operable to sum the output of the selected one of the stored values in the register 1702 with an accumulated value stored in an associated accumulator register 1710, one each for each of the ADCs 342. For the current embodiment described, there are sixteen ADCs 342 and, thus, sixteen receive registers 1702 and sixteen accumulator registers 1710. The summing operation is illustrated by a line 1709 which transfers the sum back to the accumulator register 1710 for each generation of a V_{IN} pulse and the auto zero/transfer/conversion operation for the predetermined number of times. The receive count accumulator clock that cycled through each of the registers 1702 will also cycle through each of the accumulator registers 1710. For each count value of the receive accumulator counter 1703 (all of which are based on the self-clocked MTR clock), the value in the accumulator register 1710 for that count will be processed, depending upon the particular data mode. The value from each accumulator register 1710 can be transferred to an SFR (Special Function Register) 1712, the output of which is interfaced with the DMA 354 to allow for direct access to the memory 356 at the appropriate location. There will also be provided a receive sequencer 1714 which is operable to determine the order of access of the accumulator registers 1710 when transferring data. This is controlled by a receive sequence counter 1718.

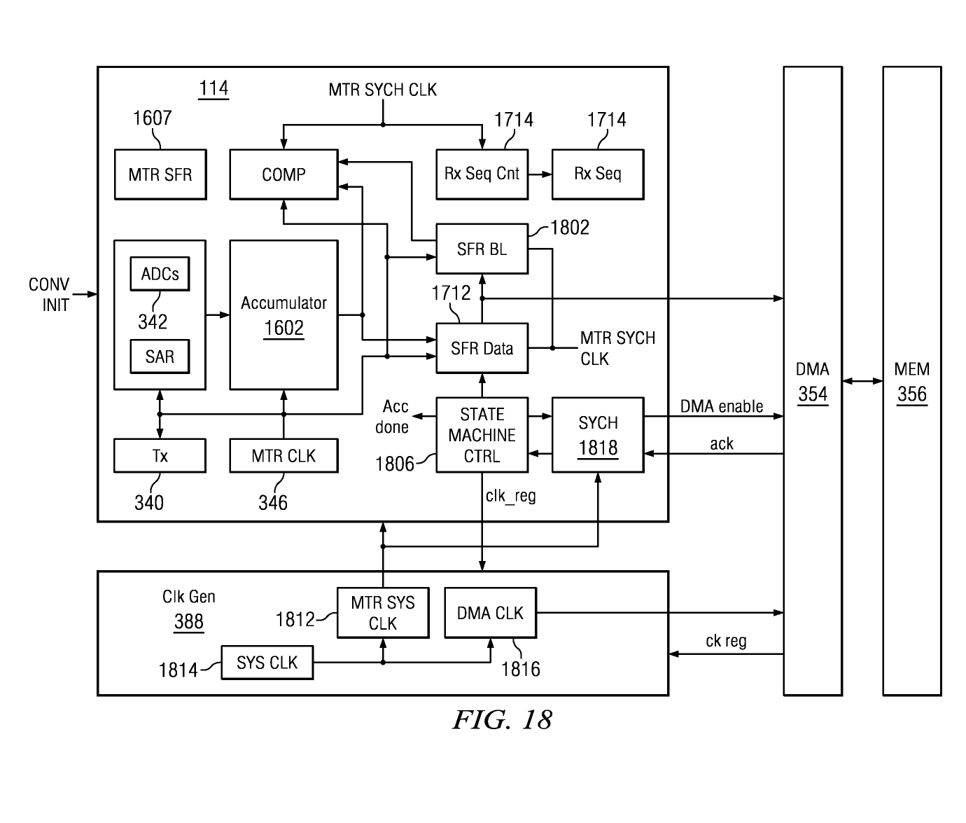

Referring now to FIG. 18, there is illustrated a block diagram for the interaction between the MTR module 114 and the DMA 354. The core portion of the MTR module 114 is comprised of two portions, one portion working exclusively within the MTR clock domain and the second portion operating within the SYSCLK domain. The operation of processing receive data after a CONV INIT operates in the MTR clock domain with the ADCs 342 converting the charge on C_{RCF} to a digital value in conjunction with the SAR engine to provide an output to the hardware controller 1602. As noted herein above, the block hardware controller 1602 can operate with an accumulation of X1 up to X64 or any number. After the accumulations have been completed, then internal processing can be effected to determine if a touch has occurred, to determine the magnitude of that touch or to just transfer the accumulator results to memory. In any of these scenarios, access to the memory is effected through the DMA 354. However, in this direct data transfer operation, whether it be retrieving the baseline data or writing data to the memory, requires access to the XRAM memory 356. This operation, in exemplary embodiments, requires everything to be synchronized with the SYSCLK output, thus, there will be an MTR clock domain and a SYSCLK clock domain. As noted herein above, data transfer is effected with SFRs. For the MTR operation, this will utilize two SFRs, one for transfer of the data from memory 356 to the MTR module 114 and one for transferring data from the MTR module 114 to the memory 356. The transfer of data from the MTR module 114 to the memory 356 is effected via the data SFR 1712. A second SFR 1802 is utilized for reading of data from the memory 356, this being the baseline data. The DMA 354 is configured via an SFR which defines the plurality of “clients” within the system. When a request is received from a particular client, the configuration data that is preloaded for the different data modes, for example, will define the initial address in memory to which to store data and the number of data transfers that will occur. Therefore, if there are 16 Rx channels and 16 Tx channels for a data storing mode for the MTR function, the DMA SFR for that operation will recognize that the start of the data transfer mode begins at the first Rx channel for the first strobe on the first Tx channel. An internal DMA counter will sequence through the addresses for each data transfer request from the State Machine controller 1806 of the MTR module 114 until no more requests are received. Of course, this requires the MTR SFR 1607 in the MTR module 114 to coordinate with the SFR in the DMA 354 via an initial set up process.

As noted, for the MTR module 114 data transfer operation, two SFRs, the SFR 1712 and the SFR 1802 will be utilized. Each of these constitutes a client to the DMA 354. Therefore, for a data transfer operation of data from SFR 1712 to memory 356, the DMA 354 recognizes the request for such data transfer as coming from the SFR 1712 client and it will respond with an operation that causes data to be transferred to the memory 356 to the appropriate address in accordance with the setup in an internal DMA SFR. That SFR 1712 is associated with one client. If the baseline data is to be transferred, the transfer operation is associated with a second “client” that will result in a Read of data from the baseline area of the memory 356 at the appropriate address for the appropriate Tx channel and Rx channel and transmit it to the SFR 1802 for the compare mode and the subtract mode, as will be described herein below.

For the data transfer operation, the SFRs 1802 and 1712 and the receive sequencer operation will operate in the SYSCLK clock domain. Thus, after the accumulation operation, operating the MTR clock domain, all of the accumulators results will also be stored in the accumulator registers 1710 associated with each of the Rx channels. Once this is complete, a clock request is sent out to the clock generator 388 for a peripheral clock. This will turn on one peripheral clock block 1812 that is synchronized with the SYSCLK, as represented by block 1814. As noted herein above, by turning off the clocks when not needed, power savings can be effected. Additionally, even if the SYSCLK is turned off, it can actually be turned on in order to provide the synchronizing clock data. The State Machine control block 1806 will generate an enable signal for the DMA 354 in the event that the DMA is in a sleep mode. It is noted that the DMA need not be powered up and operating when data is not being transferred. DMA 354 will also send a clock request to the clock generator 388 in order to turn on a peripheral clock block 1816 to generate the peripheral clock for the DMA 354. Of course, if the DMA is operating to either service another peripheral block or in the event that the MCU is in the normal operating mode and not in the sleep mode, then there is no necessity to generate another clock request from the DMA. Further, the State Machine control block 1806 will also receive information as to whether the DMA 354 is busy with another transfer operation and, in essence, effect a hand shake therebetween. This is in the form of enable signals to the DMA 354, data requests, acknowledgments back from the DMA 354, etc. All control outputs for the State Machine 1806 will be synchronized with the edge of the system clock. As such, there will be a synchronization circuit 1818 associated with this operation, there being one block illustrated for such. This will provide an MTR synchronized clock that will control the operation of the SFRs, receive sequencer, etc.

Once the transfer operation has been effected, the receive sequencer 1714 determines the order in which the data is transferred from the accumulator 1710 to the SFR 1712 for outgoing data and the order in which data is transferred to the SFR 1802 for input to the comparator and for the subtraction mode. It should be understood that there could be provided 16 separate data transfer SFRs, one for each accumulator register 1710. However, this would require for there to be a data request associated with each SFR to the DMA 354 so that it could recognize which SFR to address, i.e., each SFR would be a client to the DMA. By utilizing a single SFR 1712 and the counter and the receive sequencer, a single multiplexed SFR 1712 is utilized. The receive sequencer is pre-loaded with the appropriate value for given Rx channels from “0” to “15.” In the default mode, these are provided in the normal sequence order. There are therefore provided 16 receive sequence register values, each associated with a particular Rx channel. There will be provided a start value for the Rx sequencer and an end value such that, for example, the sequence could be started at the Rx sequencer register “0” and terminate with the Rx sequencer register “15.” It could be that only the values in the accumulator register 1710 associated with Rx sequencer register “8” through “12” are necessary to evaluate and this would be set in the MTR SFR 1607 as the starting and stopping registers. Now, the registers in the Rx sequencer are mapped to the particular Rx channels. These could be in the sequence as set forth in the pinout portion of the chip or it could be mapped to different channels. It may be that, due to layout considerations, that the particular columns, C0, C1, C2 are mapped to Rx channels Rx5, Rx4, and Rx3. By loading these values in that order, and controlling the Rx sequencer, it is then easy to count the sequence through the count with the counter 1718. Thus, the order in which Rx pins are mapped in the MTR SFR 1607 will define the sequence of the columns as they are mapped into the memory 356. The start and stop values stored in the MTR SFR 1607 will define the beginning and the end of the scan and it also allows for less than all of the columns to be scanned such that a portion of the touch screen display can be scanned.

With reference to FIGS. 16, 17 and 18 the general operation, as described herein above, is an operation that is shared between the MCU 302 and the peripherals, one being the MTR module 114 for a scanning operation. With specific reference to the interaction of the MTR module 114 and the CPU, the power saving aspect of the interaction between the two involves minimizing the amount of processing by the CPU 302 and associated digital circuitry such as the clock, memory and digital peripherals, as well as the analog peripherals required to generate the necessary control signals to setup and initiate operation of the hardware aspects of the MTR module 114. After setup and scan initiation, the MCU will be placed in idle mode. In the idle mode, the MCU is at a reduced power level. Once the hardware operation of the scan is initiated, the power utilized by the MTR module 114 will be a factor in the overall power budget. Thus, utilizing the hardware aspects of the MTR module 114, the various scanning modes can be set up by the MCU and then initiated and the MTR module 114 takes over after that.

There are multiple scan modes for determining if there has been a touch and the strength of that touch. These operations involve generating a pulse and transmitting it to a specified row and sensing the output from all of the columns (noting that the transmit pulse could be input to a column and sensing effected from the rows). This operation involves some type of initiation for the “conversion” operation followed by converting the charge into a digital value, accessing memory for a Read, a Write or a Read/Write followed by generation of some type of interrupt. The initiation of conversion can be initiated by either Writing a bit to the MTROBUSY bit of the MTR SFR 1607, an overflow of one of the timers, an output of the RTC from an internal RTC timer or some type of external trigger, noting that this will be a synchronous trigger that will be synchronized with the MTR clock. The conversion mode is either a single strobe mode requiring one Tx and multiple Rx or a panel scan mode requiring multiple strobes defined by starting and ending Tx channel.

The data modes are comprised of four modes. The first is the SFR mode wherein the MCU reads data form the SFR. The second mode is the DMA mode wherein the data is dumped into the DMA. These involve two types of modes. The first is where data is transmitted to the DMA via a request to the DMA for transfer followed by an acknowledgement from the DMA and the second is for the DMA burst mode where there is one DMA request for multiple channels. A third mode is the compare mode wherein the data is compared with the DLBL-RAW>TH. (RAW may be larger than DLBL). A fourth mode is a subtract mode (SUB mode) which requires the value of DLBL-RAW to be stored in the DMA. In the last two modes, both DMA writing and reading are required. There will be various interrupt flags generated. There are provided four different DMA flags, one for the “conversion done” after each strobe, one for the “conversion done” after each panel scanning operation, one for the “less than event” (a touch detected) during the compare mode and one for a DMA time out.

In the single strobe mode, the MCU will go into fully active mode and set up the scan by defining which type of hardware mode will be entered and various parameters of the scan such as what row line or MTR Tx pin will the scan be initiated at and the such. An initiating signal will then be sent and the MCU will go into the sleep mode. During the setup mode, the MTR module 114 will process the setup information provided by the MCU. If it is the single strobe mode, a single row will be serviced by the MTR module 114. This operation could be operating in any one of the four data modes. In the single strobe mode, an interrupt will be generated at the end of servicing each row and then the MTR module 114 will wait for the next initiating command and will select the next row unless the MCU generates additional information to start at a different row, i.e., different Tx channel. In the panel scanning operation, the initial row Tx channel number is defined and then the scanning operation will go through multiple rows until an end row Tx channel number is reached. This is controlled by the Tx counter. Therefore, all that is involved is for the MCU to store in the MTR SFR 1607 the start and end transmit channels for the scanning operation. At the end of the panel scanning operation, a “panel scan done” flag will be set as an interrupt. For the simplest panel scan, this involves nothing more than to determine if the difference between the raw data (the digital value associated with the accumulated digital charge values) and the prestored baseline value falls below a prestored threshold value, which threshold value is stored in the MTR SFR 1607. If this value falls below the threshold voltage, a flag is generated indicating that a touch has occurred and the scan operation stopped. If not, the scan continues involving only access to the memory though the DMA for a Read operation to access the baseline values for each row. This occurs after all of the accumulation operations for a given single strobe of a row. There are also two modes that are data collection modes that will occur after a touch has been detected. In these modes, only the strength of the value is collected and transferred in a Write operation to the memory. Raw data could also be transferred in the DMA data collection mode. Thus, the MTR module 114 and the receive sequencer 1602 can operate in data collection modes to either collect data for transfer directly to the MCU for processing by the CPU 302 from the SFR 1712 without the use of the DMA, it can access the DMA for processing the baseline value, it can access the DMA for downloading data thereto or it can just inform the CPU 302 of some type of action that needs to be taken. All of these operations are effected in a hardware State Machine such that the MCU can be placed in the sleep mode during such operation.

The DMA mode is a mode that transfers data to the DMA. The data is collected and, at the end of a strobe (after all accumulation operations are finished), the DMA 354 will receive a DMA request from the MTR module 114 which will cause the DMA 354 to generate a clock request to the system clock generator block 376 to generate the DMA clock. The DMA will then interface with the SFR 1712 and sequencer 1714 to transfer the contents of the accumulator registers 1710 to memory. Once the DMA 354 has transferred all the data, this operation will be complete.

The Compare mode is touch/no-touch mode. This involves the MTR module 114 to access baseline information stored in the memory. This baseline information is stored in one region of the memory such that there is one digital charge transfer value for each capacitor in the array. As described herein above, this operation is performed during a calibration operation. Thus, all that is required is to perform a memory access operation, i.e., a Read operation. There is no Write operation required. The Baseline (BL) data will be stored in a separate SFR (not shown). This will be output to the comparator 1711, all in accordance with the sequencer operation of receive sequencer 1714. The purpose of the comparator 1711, which is a shared digital comparator, is to compare the difference between the digital value from the corresponding accumulation register 1710 (raw data) and the baseline value with the threshold value to determine if it is less than the threshold value. As such, this is a “less than” comparator 1711, but it should be understood that a “greater than” comparator could be utilized. If it is a “less than” comparator, a touch condition will be declared when above the threshold and if it is a “greater than” comparator, a no-touch will be declared when above the threshold. In the described embodiment, the “less than” comparator 1711 will go high for a decision that a touch has occurred. In the event that a touch does occur for any comparison operation, the operation of the MTR module 114 will be halted and an interrupt generated to the MCU to basically take the MCU out of idle mode such that it can then initiate whatever operation is necessary to service a touch detection. This will typically result in the MCU 302 generating sufficient control and set up information to cause the MTR module 114 to enter a different mode and scan the entire panel and collect data for storage in a predetermined location in the memory. It is not necessary during a touch/no-touch detection operation to store any information in the memory, i.e., consume power to do such.

When the MCU receive an indication of a touch detection, it will then go into a mode where it will collect data. This data is collected by utilizing the subtract (SUB) mode. In the subtract mode, the actual strength value is what is transferred to the memory. This is compared to the DMA mode wherein raw data is dumped to the memory. For the subtract mode, the first step is to access the baseline data for the particular accumulation register 1710 evaluated and then subtract therefrom the raw data stored in the register. This will then be compared in the digital comparator 1711 to the threshold value stored by the user. A decision is then made to write a “0” to the memory location associated with the particular C_{RCF} if the difference between the baseline and the raw data is greater than threshold and, if it is less than threshold, then the amount that it is below the threshold, i.e., the strength value, will be stored. This is a data population mode (as is the DMA mode). Thus, the MCU will control the MTR module 114 to evaluate each row, accumulate results for each row over the number of accumulations programmed therein, store the strength values and sequence through all of the rows until the panel has been completely scanned. Also, it is possible for the MCU to select certain rows and columns to be evaluated. For example, if it were determined that the touch detection occurred at row 15 in a 32 row display, it would make sense to only collect data from row 15 and up. Additionally, it is possible through the programming of the sequencer to restrict the columns transferred to the memory in this situation where the touch detect did not occur until column 3 in a 16 column display. Again, this is a function of the scanning strategy that is programmed into the MCU.

In the panel scanning mode, the entire panel is scanned in a repetitive operation. All that is required is, after setting the mode to panel scanning, to set the start and stop Tx channels in the MTR SFR. The number of Rx channels can also be set if not all Rx channels are selected for the scan operation. This is the function of the size of the panel and the number of Tx pins and Rx pins that are utilized. After each strobe is completed, the “single strobe conversion done” flag will be set after the accumulation is completed for that strobe of a row. After the last “single strobe conversion done” flag is set, the “panel scanning conversion done” flag will be set in the same clock cycle. If, the selected mode in the panel scanning mode is to transfer data to the DMA, the timing is such that all data be logged before the next conversion operation is initiated on a time out flag may be set for such operation to ensure that the parallel conversion operation is completed before the next accumulation.

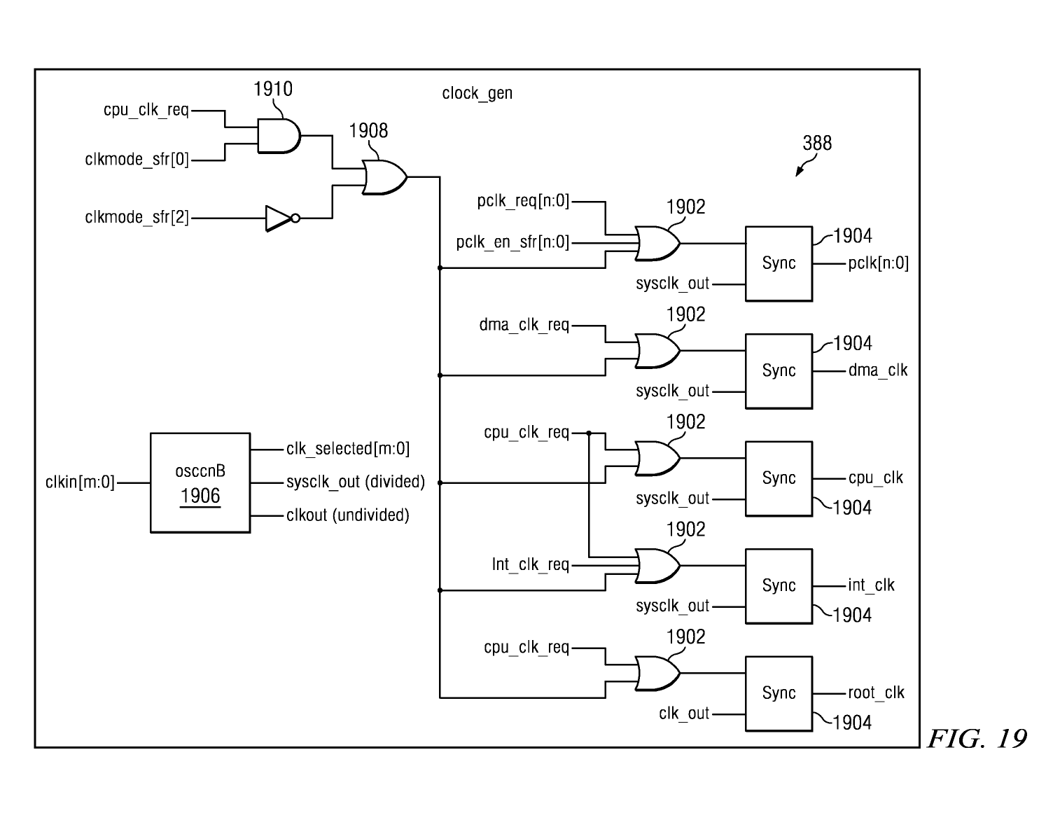

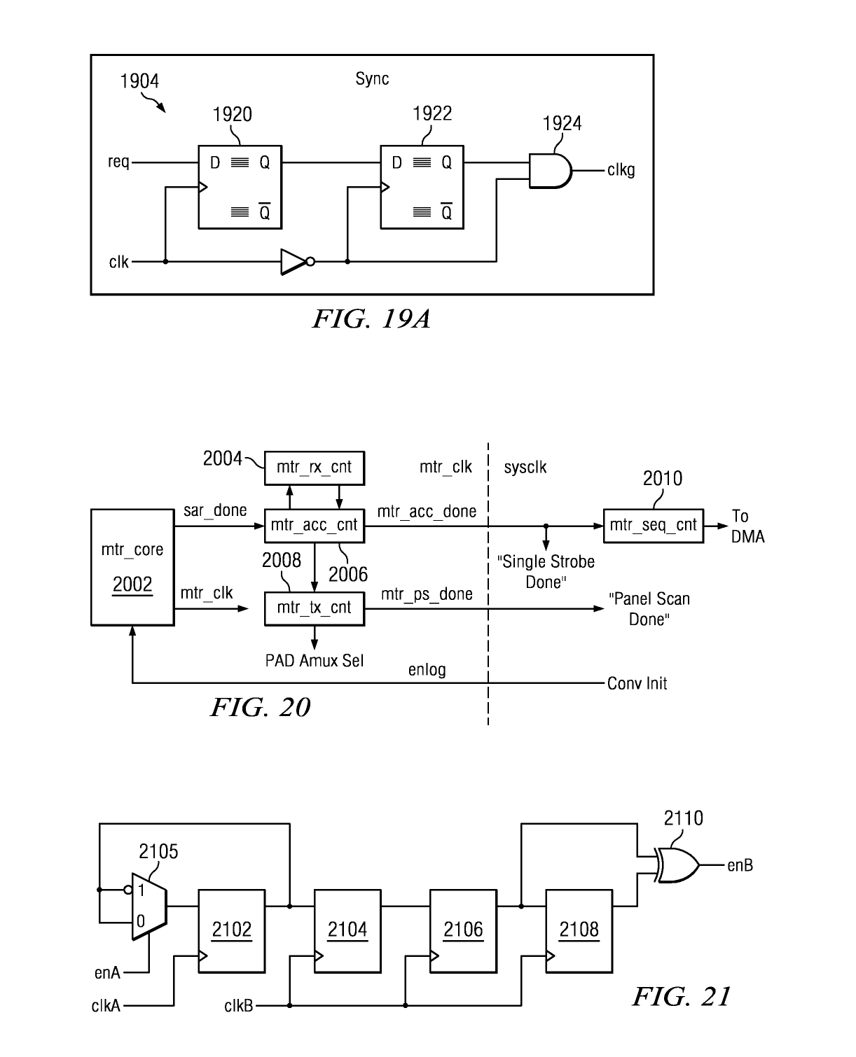

Referring now to FIG. 19, there is illustrated a block diagram of the clock generator 388. The clock generator is comprised of a plurality of multi-input OR gates 1902, each operable to receive a clock request from one of the peripherals and provide the output request to a SYNC block 1904, there being one SYNC block associated with each of the OR gates 1902. Various clock sources input to block 1906 are operable to generate various clock selected outputs, a SYSCLK output, a divided clock output and a CLKOUT output—an undivided clock output. Each of the OR gates 1902, in addition to receiving the clock request, is also operable to receive a logic output from an OR gate 1908. One input of the OR gate 1908 is connected to a bit in a clock mode (CLK MODE) SFR and the other input thereof connected to the output of an AND gate 1910. One input of AND gate 1910 is connected to a CPU clock request input and the other connected to a clock mode output from a configuration SFR. When the CPU clock request is received and the clock mode is appropriate, this will enable the output of all of the OR gates 1902. In the absence thereof, the output will be in response to a clock request.

There are illustrated five different clock requests, one for a peripheral clock, one for the DMA, one for the CPU, and another for the internal CPU clock. These will provide, respectively, a peripheral clock output, a DMA clock output, a CPU clock output, an internal clock output and a root clock output. The peripheral clock is synched with the SYSCLK, as is the DMA clock, the CPU clock and the internal clock. However, the root clock is synched with the undivided CLKOUT. The MTR is clocked with a peripheral clock block.

Referring now to FIG. 20, there is illustrated a block diagram of a basic MTR module 114 digital hierarchy. There is provided an MTR core 2002 that performs the SAR and contains the MTR clock. The MTR core provides, at the end of the SAR operation, a sar_done signal. There are provided three counters, an MTR receive counter 2004, an MTR accumulation counter 2006 and an MTR transmit sequence counter 2008. The receive (Rx) counter 2004 interfaces with the accumulation counter to input counts to each of the receive channels for the accumulation operation. Once the accumulation is complete for all of the receive channels, the MTR transmit (Tx) counter 2008 will select the next pad or Tx channel. The counters 2004-2008 and the MTR core 2002 are all in the MTR clock domain. When the MTR accumulation counter 2006 is complete, i.e., all of the accumulations are complete for one strobe, the mtr_acc_done signal is output to the SYSCLK domain. This goes to the MTR sequence counter, represented by a block 2010. This sets a flag for the single strobe done. Additionally, there is an mtr_ps_done signal output from the MTR transmit counter 2008 indicating that a panel scan has been complete, the setting of a flag “panel scan done” on the SYSCLK side. On the SYSCLK side, the conversion initiation signal will be provided as an input, this is referred to as the enlog signal, to the MTR core 2002 which will initiate the next conversion cycle, i.e., the generation of the transmit signal and the SAR conversion operation. The MTR sequence counter 2008 provides an output to the DMA and controls the transfer operation, as set forth herein above with respect to FIGS. 16 and 17.

Referring now to FIG. 21, there is illustrated a block diagram for the synchronization operation for synchronizing between two clocks, i.e., the MTR clock and the SYSCLK. A first clock, clkA is input to the clock input of a flip-flop 2102, the D-input connected thereof to the output of a multiplexer 2105, where two inputs thereof are connected to the Q-output of flip-flop 2102 with one being inverted such that a zero on the output will result on a one on the input. This is enabled with a signal enA, the input edge. The clkA signal will clock through the output of the multiplexer 2105 to the input of a second flip-flop 2104, which will be chained with two other flip-flops 2106 and 2108. Each of these is clocked with the second clock, a clkB. The output of the second flip-flop 2106 is input to one input of an exclusive OR gate 2110, the other input thereof connected to the output of the flip-flop 2108. This provides the enB edge on the output thereof.

It will be appreciated by those skilled in the art having the benefit of this disclosure that this touch screen scanning architecture provides a lower power operation by utilizing hardware scan controllers in combination with an MCU engine. It should be understood that the drawings and detailed description herein are to be regarded in an illustrative rather than a restrictive manner, and are not intended to be limiting to the particular forms and examples disclosed. On the contrary, included are any further modifications, changes, rearrangements, substitutions, alternatives, design choices, and embodiments apparent to those of ordinary skill in the art, without departing from the spirit and scope hereof, as defined by the following claims. Thus, it is intended that the following claims be interpreted to embrace all such further modifications, changes, rearrangements, substitutions, alternatives, design choices, and embodiments.

What is claimed is:

1. A method of interfacing with a capacitive touch screen, comprising:
charging an internal capacitor in the touch screen, which internal capacitor is disposed proximate a fixed location on the touch screen and is capable of changing in value in response to a touch at the fixed location; and
determining the value of the charge on the internal capacitor.

2. The method of claim 1, further comprising comparing the value of the determined charge with a reference value which corresponds to a no-touch condition to determine if the value of the determined charge has changed beyond a delta from the reference value, which is representative of a touch condition.

3. The method of claim 1, wherein determining the value of the charge comprises transferring charge in a transfer operation from the internal capacitor in the touch screen and then determining the value of the charge in isolation of the internal capacitor.

4. The method of claim 3, wherein determining the value of the charge comprises transferring the charge from the internal capacitor to a reference capacitor disposed at a reference charge prior to the transfer operation and, after transferring, determining the change in charge on the reference capacitor, the change in charge corresponding to the charge stored in the internal capacitor.

5. The method of claim 4, further comprising converting the change in charge to a digital value.

6. The method of claim 1, wherein the touch screen is comprised of row lines and column lines arranged in an intersecting relationship to each other and electrically isolated from one another and the internal capacitor comprises a mutual capacitance between the intersection of one of the row lines and one of the column lines.

7. The method of claim 6, further comprising connecting one of the row or column lines to a driving voltage that can change in voltage level from an initial value to a charge transfer value and connecting an intersecting other of the row or column lines to a reference capacitor disposed at a voltage different than the initial voltage and the determining operation comprising changing the voltage level of the driving voltage and transferring the charge on the internal capacitor in a transfer operation to the reference capacitor and then determines the change in charge thereon as the value of the transferred charge on the internal capacitor.

8. The method of claim 6, wherein each of the intersections between row and column lines has an internal capacitance associated therewith an associated mutual capacitance and the charging operation comprises:
selecting one of the row or column lines;
generating a charging signal; and
driving the selected one of the row or column lines with a charging signal to store charge on at least one of the internal capacitors associated with the intersection of the selected one of the row or column lines and an intersecting other of the column or row lines.

9. The method of claim 7, wherein driving the selected one of the row or column line charges all of the internal capacitors associated with such driven selected one of the row or column lines and the determining operation comprises determining the value of the charge on each of the internal capacitors associated with each of the other of the column or row lines intersecting with the driven selected one of the one of the row or column lines.

10. The method of claim 8, further comprising controlling the operation of driving to sequentially drive each of the selected one of the row or column lines and storing the determined charge after determining the value of the charge transferred

11. The method of claim 9, further comprising discharging substantially all of the internal capacitors in the touch screen prior to the operation of driving.

12. The method of claim 11, further comprising:
repeating the charging operation and the determining operation preceded by discharging substantially all of the internal capacitors in the touch screen for a predetermined number of times;
storing the determined values of the charge for each charging and determining operation; and
analyzing the stored values to yield an accumulated value that will account for variations in the stored charge on the internal capacitor at any of the charging and determining operations.

13. The method of claim 11 wherein analyzing comprises summing all of the results for each charging and determining operation and dividing by the number of charging and determining operations.

14. The method of claim 11, wherein analyzing comprises summing the results of the charging and determining operations to provide the accumulation result.

15. The method of claim 11, wherein each of the charging and determining operations are varied in time relative to each other to remove periodicity therefrom.

16. A method of determining the value of an initial capacitance between a row line and a column line in a capacitive touch screen comprising a plurality of intersecting row and column lines, comprising the steps of:
driving one of the row or column lines to a first voltage with an intersecting one of a column or row lines being connected to an external node external to the launch screen to charge the mutual capacitance at the intersection, the external node having a reference capacitor disposed thereon charged to a reference voltage;
driving the one of the row or column lines to a second voltage with the reference node controlled to allow charge to be transferred between the mutual capacitance and the reference capacitor; and
determining the value of the change of the charge on the reference capacitor.

17. The method of claim 16, further comprising storing the determined value.

18. The method of claim 16, further comprising isolating the reference node from the touch screen prior to determining the value of the change in charge on the reference capacitor.

19. The method of claim 16, wherein determining the value of the change in charge on the reference capacitor comprises converting the determined value to a digital value with an analog-to-digital converter.

20. The method of claim 18, wherein the reference capacitor comprises a plurality of binary weighted capacitors, each configurable to be connected in parallel between the external node and ground when a charge is transferred between the mutual capacitance and the reference capacitor or selectively between the external node and a second voltage to redistribute charge during determining the value of the change in charge on the reference capacitor, and wherein determining the value of the change in charge on the reference capacitor further comprises configuring the binary weighted capacitors in accordance with a SAR analog-to-digital converter algorithm to set the voltage on the external node to substantially the reference voltage, the digital value of such configuration representing the determined value and the charge that was stored on the mutual capacitance during driving one of the row or column lines to the first voltage.

21. The method of claim 16, wherein driving the one of the row or column lines to the first voltage and driving the one of the row or column lines to the second voltage and determining the value of the change in charge on the reference capacitor are repeated a plurality of times preceded by discharging the mutual capacitance, and the determined values for each repeated operation is averaged such that changes in the charge due to external noise or perturbations can be averaged between repeated operations.

22. The method of claim 21 wherein the times between the repeated operations is aperiodic.

23. The method of claim 21, wherein the aperiodic timing is a random timing relative to each of the repeated operations.

24. A method for determining the value of charge on a Capacitor Under Test (CUT), comprising:
charging a reference capacitor on a first node to a first charge level;
transferring a substantially fixed percentage of the charge between the CUT and the reference capacitor such that the charge on the reference capacitor changes by the substantially fixed percentage of the charge transferred;
isolating the CUT from the reference capacitor;
determining the change in charge on the reference capacitor; and
correlating the change in charge on the reference capacitor to the value of the charge on the CUT.

25. The method of claim 24, wherein correlating the change in charge comprises converting the change in charge on the reference capacitor to a digital value and further comprising storing the digital value in a memory.

26. The method of claim 24, wherein the first charge level on the reference capacitor corresponds to a first voltage level and wherein transferring the charge between the CUT and the reference capacitor varies the voltage on the reference capacitor, and determining the change in charge on the reference capacitor comprises incrementally distributing the charge on the reference capacitor to another capacitor in accordance with a Successive Approximation Register (SAR) algorithm until the voltage level across the reference capacitor equals the first voltage level.

27. The method of claim 24, wherein the reference capacitor comprises a binary weighted capacitor comprised of a plurality of binary weighted discrete capacitors and wherein the first charge level on the reference capacitor corresponds to a first voltage level on a first plate of the reference capacitor and transferring the charge between the CUT and the reference capacitor comprises varying the distribution of charge to the one plate of the reference capacitor by selectively connecting the discrete capacitors between the first node and either a ground voltage or a supply voltage.

28. The method of claim 27, wherein charging the reference capacitor to a first voltage comprises connecting the first node to a virtual ground node of an operational amplifier charged at the first voltage level configured as a unity gain amplifier and, during the operation of determining, configuring the operational amplifier as a comparator during the transferring operation with a reference input connected to the virtual ground voltage associated with the charging operation such that the SAR operation determines a distribution of the discrete capacitor between either ground or the supply voltage to dispose the first node at the first voltage level for the determining operation.

29. The method of claim 24, wherein the CUT comprises a capacitor representing the mutual capacitance between intersecting row and column lines in a touch screen display.

30. A capacitance value sensor for determining a capacitance value corresponding to the value of an internal mutual capacitance in a touch screen display having intersecting first lines and second lines with the mutual capacitance disposed at the intersection of one of the first and second lines, comprising:
a driver for driving the one of the first lines to drive one plate of the mutual capacitance from a first voltage to a second voltage level; and
a capacitance sense circuit, including:
a reference capacitor having one plate thereof connected to ground and the other plate thereof connected to a voltage node,
a charging circuit operating in a first mode to connect the voltage node to the one of the second line with the driver operating to drive the one plate of the mutual capacitance to the first voltage level, the charging circuit charge the reference capacitor to a reference voltage level,
transfer circuitry operating in a second mode and cause the driver to change the first voltage from the first to the second voltage level to transfer charge from the mutual capacitance to the reference capacitor, and
a charge detect circuit operating in a third mode for determining the change in charge on the reference capacitor after transfer of charge thereto from the mutual capacitance and outputting a value for such change in charge, which value corresponds to the value of the mutual capacitance.

31. The capacitance value sensor of claim 30, and further comprising an isolation circuit for isolating the mutual capacitance from the voltage node prior to the third mode of operation.

32. The capacitance value sensor of claim 30, wherein the charging circuit comprises a unity gain operational amplifier for charging the reference capacitor to a virtual ground voltage comprising the reference voltage by disposing the voltage node at the reference voltage.

33. The capacitance value sensor of claim 32, wherein the transfer circuitry comprises the operational amplifier configured as a feedback amplifier such that the voltage node is configured as a high impedance node.

34. The capacitance value sensor of claim 33, wherein the reference capacitor comprises a binary weighted capacitor comprised of a plurality of binary weighted discrete capacitors all having one plate thereof connected to the voltage node and the other plate thereof selectively connectable to either ground or a supply voltage, the charge determination circuit comprising a successive approximation register (SAR) data converter for distributing the other plates of the discrete capacitors from an initial connection to ground to either ground or the supply voltage in a distribution in accordance with a SAR algorithm until the voltage on the voltage node is equal to the reference voltage, at which time the distribution of the capacitors represents a digital value corresponding to the value of the mutual capacitance.
